(19) United States
(12) Patent Application Publication
(10) Pub. No.: US 2026/0361054 A1
(43) Pub. Date: Nov. 12, 2026

(54) OPTICAL RIDGE WAVEGUIDE DEVICES WITH HIGH CONTRAST WAVEGUIDE GRATINGS AND METHODS OF FABRICATION THEREOF

(71) Applicant: Mellanox Technologies, Ltd., Yokneam (IL)

(72) Inventors: Uziel KOREN, Haifa (IL); Yuri BERK, Kiryat Tivon (IL); Oren STEINBERG, Tal Shahar (IL); Moshe ORON, Haifa (IL); Guy SERI, Haifa (IL); Filip Leonard HJORT, Partille (SE); Isabelle CESTIER, Haifa (IL); Elad MENTOVICH, Tel Aviv (IL)

(21) Appl. No.: 19/200,806

(22) Filed: May 7, 2025

(51) Int. Cl. H01S 5/227; H01S 5/40; H04B 10/40; H04J 14/02

(52) U.S. Cl. CPC H01S 5/2272; H01S 5/2275; H01S 5/4031; H04B 10/40; H04J 14/03

(57) ABSTRACT

According to certain embodiments, a device is provided that includes an optical ridge waveguide. The optical ridge waveguide includes a first cladding layer; a second cladding layer; a core layer stack disposed between the first cladding layer and the second cladding layer; and a first grating disposed between the core layer stack and one of the first cladding layer or the second cladding layer. The first grating includes alternating periodic regions of a semiconductor material and an oxidized material.

### BACKGROUND

As artificial intelligence and/or machine learning use increases, the amount of information being communicated between large clusters of computing resources (e.g., graphical processing units (GPUs), central processing units (CPUs), data processing units (DPUs), and/or the like) is also increasing. Short reach low power and high bit rates optical transceivers can be used to increase the density of interfaces between clusters of computing resources. However, conventional implementations of high bandwidth transmitters tend to require substantial power consumption. Accordingly, a need exists for power efficient optical sources for use in datacenters applications.

### GENERAL DESCRIPTION

Datacenters rely on a fast and robust communication infrastructure. This is achieved by using optical interconnects, especially between different server racks. Each physical link may include multiple communication channels, carried on multiple fibers. Such optical interconnects tend to include transceivers that are in optical communication with one another via one or more optical fibers. A transceiver includes one or more optical signal generating components and/or one or more optical signal detecting components. For example, a transceiver may include one or more semiconductor devices (e.g., vertical cavity surface emitting lasers (VCSELs); distributed-feedback (DFB) lasers; comb lasers; light emitting diodes (LEDs); modulators such as electro-absorption modulators, intensity and/or phase modulators, and other modulators; electro-absorption modulated lasers (EML); and/or the like) configured to generate optical signals and/or one or more semiconductor devices (e.g., photodiodes) configured for detecting optical signals.

The transmitters in short reach optical transceiver modules are typically based on arrays of discrete single wavelength lasers, such VCSELs. The VCSELs may then be directly modulated to generate optical signals having digital data streams encoded thereon. Forthcoming optical links require optical transmitters capable of operating with high bandwidth (BW) in the range of 30-120 GHz and beyond. Conventional sources, such as VCSELs, are not currently capable of meeting these high bandwidth requirements. Additionally, it is desired to for optical sources to have reduced power consumption requirements. For example, it is desired to have lasers with small threshold currents and high quantum efficiency.

As transceivers increase their line bitrate, currently from 25 Gbit/s to 50 Gbit/s and then to 100 Gbit/s, as well as upgrade the modulation order from present techniques like non-return-to-zero (NRZ) to pulse amplitude modulation level 4 (PAM-4), the challenge is how to reduce the power consumption of the transmitter, and reduce heat dissipation strain and thermal management challenges.

This is particularly relevant for transceivers that need to be encapsulated in standardized pluggable forms, which have limited heat dissipation properties and small space, such that they rely on air flow design, thereby limiting the amount of power transceivers can take from the main rack by the form-factor standards.

Various embodiments provide short cavity edge emitting semiconductor lasers. In various embodiments, the optical cavity of an example laser is defined at least in part by a Bragg reflector and/or a high-contrast waveguide grating. The high contrast waveguide distributed Bragg reflector (DBR) gratings, enables for enhancing the performance of semiconductor lasers used in optical interconnects. For example, the high-contrast waveguide grating may comprise alternating periodic regions of a semiconductor material and an oxidized material. For example, in some embodiments, the contrast of refractive indices between the semiconductor material and the oxidized material can be 1.3 or greater. For example, the contrast of refractive indices between the semiconductor material and the oxidized material can be in a range of 1.3-2.0. An array of such semiconductor lasers, where coupled to external modulators and where each laser is configured to emit a laser beam/pulses of a different wavelength may be used to provide a WDM source. For example, such arrays may provide high modulation bandwidth while still requiring acceptable power consumption. Dense low-power interfaces are paramount to continue scaling AI/ML systems to interconnect large clusters (GPUs, CPUs, DPUs, ....). Compared to a multiple directly modulated VCSEL implementation, various embodiments provide optical sources with higher bandwidth and not much higher or comparable power consumption.

In certain applications, a semiconductor laser may be coupled to an output waveguide (e.g., directly, evanescently, and/or the like). The output waveguide may be used to optically couple the semiconductor laser to one or more modulators, multiplexers, a photonic integrated circuit (PIC), and/or the like.

In various embodiments, the semiconductor laser is monolithically integrated with a modulator. In some embodiments, a semiconductor device is provided that includes a semiconductor laser and an electro-absorption modulator (EAM) and/or an electro-optical modulator (EOM). For example, an output waveguide of the semiconductor device is configured to provide a modulated laser beam to a multiplexer, PIC, and/or the like. For example, the semiconductor device may be part of an interconnect used for optical communications.

According to an example aspect of the present disclosure, devices comprising an optical ridge waveguide are provided. The optical ridge waveguide includes a first cladding layer; a second cladding layer; a core layer disposed between the first cladding layer and the second cladding layer; and a first grating disposed between the core layer and a portion of one of the first cladding layer or the second cladding layer. The first grating comprises alternating periodic regions of a semiconductor material and an oxidized material.

In some embodiments, the device is an optical filter. For example, in certain embodiments, the first grating may be a Bragg reflector and the optical filter is a band stop filter, or the first grating may be a phase-shifted Bragg grating and the optical filter may be band pass filter.

In some embodiments, the device is a semiconductor laser, and the first grating defines one end of the laser cavity or resonator of the semiconductor laser. For example, the first grating may be a Bragg reflector. The other end of the laser cavity or resonator may be defined by another grating (e.g., another Bragg reflector) or a cleaved mirror. For example, the semiconductor laser may be a short cavity edge emitting laser.

In various embodiments, one or more of the devices may be incorporated into a transceiver of an optical interconnect or optical link within large networks. For example, devices of various embodiments in the form of optical filters may be used for filtering spectral lines of a wavelength division multiplexing (WDM) optical signal as part of a transmitter module or a receiver module of a transceiver. In another example, devices of various embodiments in the form of semiconductor lasers may be used as the optical source(s) of a transmitter module of a transceiver.

In at least one example embodiment, the optical interconnect is part of a datacenter that corresponds to a collection of network devices, such as network switches (e.g., Ethernet switches, IP routers, multiservice platforms, various transmission network elements, legacy communication equipment, or in any other suitable communication system) connected with a collection of servers or compute nodes. A switch fabric serves to transfer the data between the switch ports. A switch fabric comprises one or more interconnect circuits, which may be arranged in various switch fabric architectures, e.g., m*m crossbar, Banyan, Benes, Omega, Clos, multi-plane, STS, TST, shared memory, buffered crossbar, any other suitable blocking or non-blocking architecture, or any applicable mixed architecture thereof. A switch fabric is realized in typical embodiments by hardware, which may comprise Field-Programmable Gate Arrays (FPGAs) and/or Application-Specific Integrated Circuits (ASICs), and in some implementations also bus interconnects. The datacenter may adhere to a networking topology (e.g., a hierarchal networking topology), such as a fat tree topology, a Slim Fly topology, a Dragonfly topology, and/or the like. The datacenter routes traffic amongst the network switches and servers therein, and at least one layer of the topology in the datacenter is coupled to the communication network to allow networking traffic to flow between the datacenter and the network device(s).

The optical interconnect may include a substrate and an electro-optical component (one or more semiconductor lasers, one or more photodiodes, etc.) supported by the substrate and configured to convert electrical signals to optical signals or vice versa. The optical interconnect may further include a transmission block defining a receiving surface configured to receive an optical fiber, and a waveguide configured to transmit optical signals between the electro-optical component and the receiving surface such that in an operational configuration in which the receiving surface receives an optical fiber, the electro-optical component and the optical fiber are in optical communication.

While the present disclosure illustrates and describes the optical interconnect without a housing or other protective casing, as would be understood by one of ordinary skill in the art in light of the present disclosure, some or all of the optical interconnect may be supported or enclosed by any housing used in communications systems to protect the components supported therein (e.g., as part of Quad Small Form-factor Pluggable (QSFP) connectors, Small Form Pluggable (SFP) connectors, or the like). Furthermore, the substrate hosting the electro-optical component may be substantially rectangular shape and/or may be dimensioned (e.g., sized and shaped) for use in any communication system regardless of geometric constraints (e.g., L-shaped, squared-shaped, etc.).

In various embodiments, an optical interconnect for receiving an optical fiber may be implemented in a flip-chip configuration. In certain embodiments, the optical interconnect is configured as a flip-chip component such that a longitudinal axis of the first adiabatic transition profile of the optical interconnect and a longitudinal axis of the second adiabatic transition profile of the optical interconnect may be collinear. Said differently, the orientation of the optical interconnect in such an embodiment does not require a mirror or other reflective surface to redirect optical signals between the electro-optical component and the receiving surface. As would be evident to one of ordinary skill in the art in light of the present disclosure, however, the optical interconnect in a flip-chip configuration may also include one or more mirrors (e.g., reflective surfaces) to accommodate optical fibers received at varying angles. In some optical interconnect embodiments, only mirrors may be operationally configured to redirect light given that at some bending radii, light may remain confined to the waveguide. Accordingly, embodiments of a field replaceable modular optical interconnect unit are described that are configured to be received by a main switch system box. The field replaceable modular optical interconnect unit comprises a housing comprising at least a front panel, a rear panel, and side panels extending between the front and rear panels, a printed circuit board assembly supported within the housing, an optical module supported on the printed circuit board assembly and configured to convert between optical signals and corresponding electrical signals for respectively transmitting or receiving optical signals through a fiber optic cable, a board-to-board connector disposed on the rear panel of the housing and configured to enable electrical signals to be transmitted between the printed circuit board assembly and a main switch system box, and an external connector disposed on the front panel of the housing and configured to engage an external optical fiber for transmitting optical signals between the optical module and an external component. The field replaceable modular optical interconnect unit may be configured to be electrically connected to the main switch system box via engagement of the board-to-board connector with a corresponding connector of the main switch system box when the housing is received by the main switch system box.

In some embodiments, the optical module may be a mid-board optical module (MBOM), and/or the field replaceable modular optical interconnect unit may comprise a plurality of external connectors. For example, the external connector may be a first external connector, and the field replaceable modular optical interconnect unit may further comprise a second external connector disposed on the front panel of the housing and configured to enable transmission of electrical signals between the printed circuit board assembly and an external component connected thereto.

In some optical interconnects, short cavity edge emitting lasers may replace vertical cavity surface emitting laser (VCSEL) diodes as light emitters to transmit binary or digital data over optical fibers. However, the light source may in principle be any suitable light source and the transmitted waveform may be any suitable waveform for transmitting information. Most light emitters have a threshold current above which they substantially begin to emit light. For directly modulated lasers, increasing the current driven through the emitter from zero to above said threshold may be time consuming, and therefore a bias current is typically driven through the light source. The bias current can be set just below, at the threshold, or above the threshold, but it also is often set to be well above threshold. This bias current is often programmable so as the same circuit design may be utilized to drive different light emitters and/or be used for different applications. Additional time varying current which modulates the emission from the light emitter is referred to as the modulation current.

In some embodiments, the disclosed technique provides an electro-optical (EO) interconnect assembly comprising a pair of pluggable EO transceivers connected at respective ends of an optical fiber. The EO transceivers are typically used to connect network-connected devices (e.g., remote client switches, network adapters such as Network Interface controllers (NICs) and Host Channel Adapters (HCAs), Smart-NICs (NICs having embedded CPUs), network-enabled Graphics Processing Units (GPUs), and the like). The terms “network-connected device” and “network device” are used interchangeably herein. In certain embodiments, an optical interconnect includes a substrate, one or more optical waveguides, one or more first micro-lenses, one or more second micro-lenses, and first and second mechanical fixtures.

Various embodiments relate to interconnects (e.g., interconnect topologies) that are scalable and advantageous for networks that require a large number of all-to-all or point-to-point links between one or more node or send/receive pairs. In particular, silicon photonics interconnects or topologies are provided herein that may achieve at least moderate bandwidth between many nodes with physical, optical fiber connections. In some implementations, the one or more node or send/receive pairs are coupled with an optical fiber allowing a single wavelength to pass therebetween. In other implementations, multiple wavelengths or groups of wavelengths may be transmitted or received by nodes while simultaneously passing multiple wavelengths or groups of wavelengths to other nodes via optical fiber loops connecting three or more nodes. In some implementations, such interconnects as described herein do not rely on or include one or more of the following: wavelength synchronization between transmit and receive pairs, arbitration of the fiber(s), demultiplexers on the receiver side, and/or an optical crossbar. In some implementations, the optical interconnects may be sized to fit a face-plate form factor or as a mid-board optical connector or co-packaged optics. In some embodiments, the present disclosure provides optical interconnects for high bandwidth density applications like switches and GPUs or other processing elements. In one example, the processing elements may include central processing units (CPUs), graphics processing units (GPUs), data processing units (DPUs), quantum processing units (QPUs), a plurality of parallel processing units (PPUs), and application-specific integrated circuits (ASICs). QPUs are configured to perform one or more operations associated with a quantum algorithm. In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with.

A “node” as described herein may refer to a network switch to which a plurality of computer processing units (CPUs), graphical processing units (GPUs), data processing units (DPUs), or memory media are connected in an arbitrary number. The network switch may communicate with other network switches of the same kind to which the same processor and memory units may be connected. However, in other implementations, “node” may also refer to a processor which may be responsible for communication with all other nodes in the network or subnetwork.

An “optical fiber” as described herein can refer to a single optical fiber (e.g., including a core and a cladding) to provide unidirectional optical communication, can refer to a bidirectional pair of optical fibers (e.g., each including a core and a cladding) to provide both transmit and receive communications in an optical network, or can refer to a multi-core fiber, such that a single cladding could encapsulate a plurality of single-mode or multi-mode cores. Optical fibers can extend contiguously and uninterrupted between node or send/receive pairs (e.g., via pass-through connections) or include two or more fibers connected via fiber-to-fiber connections such that the fibers function or perform as a single fiber.

Silicon Photonics (SiP) is a technology that enables optical systems to be manufactured using silicon processes with silicon as the optical medium. Various optical components, such as interconnects and signal processing components, may be fabricated and integrated in a single SiP device. Some SiP devices are fabricated on a silica substrate or over a silica layer on a silicon substrate, a technology that is often referred to as Silicon on Insulator (SOI). In certain optical systems, a SiP device is attached to an external device to facilitate optical communications. However, it is generally difficult to accurately align light signals on the SiP with an external device that receives the light.

In certain optical systems, a SiP device is attached to an external device to facilitate optical communications. For example, the system includes one or more waveguides that carry light signals to and/or from optical chips. Examples of optical chips that can be included on the device include, but are not limited to, one or more components selected from a group consisting of facets through which light signals can enter and/or exit a waveguide, entry/exit ports through which light signals can enter and/or exit a waveguide from above or below the device, multiplexers for combining multiple light signals onto a single waveguide, demultiplexers for separating multiple light signals such that different light signals are received on different waveguides, optical couplers, optical switches, lasers that act as a source of a light signal, amplifiers for amplifying the intensity of a light signal, attenuators for attenuating the intensity of a light signal, modulators for modulating a signal onto a light signal, modulators that convert a light signal to an electrical signal, and vias that provide an optical pathway for a light signal traveling through the device. Additionally, the device can optionally, include electrical components. For instance, the device can include electrical connections for applying a potential or current to a waveguide, controlling active optical components, such as modulators, for example, and/or for controlling other components on the optical device.

According to a first aspect of the present disclosure, a device including an optical ridge waveguide is provided. In an example embodiment, the optical ridge waveguide includes a first cladding layer; a second cladding layer; a core layer disposed between the first cladding layer and the second cladding layer; and a first grating disposed between the core layer and a portion of one of the first cladding layer or the second cladding layer. The first grating comprises alternating periodic regions of a semiconductor material and an oxidized material.

In an example embodiment, the device is a semiconductor laser with a section of a waveguide comprising at least one electrically pumped active gain section comprising p-doped and n-doped cladding layers; and a first passive waveguide section, wherein the first grating is disposed inside one of the first cladding layer or the second cladding layer. As used herein, a passive waveguide is an optical element configured to guide an optical mode (e.g., a guided optical mode) along an optical path defined, at least in part, by the waveguide using physical properties of the material of the waveguide to confine and guide the optical mode.

In an example embodiment, a first axis of the semiconductor edge emitting laser extends through the first cladding layer, a core layer (along the epitaxial growth direction), and the second cladding layer and a second longitudinal axis of the edge emitting semiconductor laser extends along the light propagation direction perpendicular to the first axis, wherein the at least one electrically pumped active gain section and the first passive waveguide area are aligned with one another along the longitudinal axis.

In an example embodiment, the device comprises an active gain section and a passive or modulator section, the first grating is longitudinally disposed in a passive grating waveguide section between an active or modulator section along the longitudinal axis. The first grating comprises alternating periodic regions of a semiconductor material and an oxidized material. In an example embodiment there may be a second grating disposed in the active gain section. The second grating comprises alternating periodic regions of two different semiconductor materials without oxidation, having a lower contrast than the materials of the first grating. The second grating (having no oxidized materials) may not interfere with current injection in the active gain section.

In an example embodiment, the second grating is a distributed feedback grating and contains a quarter wavelength phase shift.

In an example embodiment, the first grating and the second grating are coupled to a laser optical mode of semiconductor laser and both the first grating and the second grating do not interfere with current injection of the active gain section.

In an example embodiment, the device further includes a third grating section disposed longitudinally on the other side of the active gain section wherein the third grating comprises alternating periodic regions of the semiconductor material and the oxidized material.

In an example embodiment, the first grating consists of a first number of periodic alternating regions and the third grating consists of a third number of periodic alternating regions, and the third number is more than the first number.

According to another aspect, an array of semiconductor lasers is provided. In an example embodiment, the array of semiconductor lasers includes a plurality of semiconductor lasers. Each semiconductor laser of the plurality of semiconductor lasers includes a first cladding layer; a second cladding layer; a core layer disposed between the first cladding layer and the second cladding layer; and a first grating disposed between the core layer and a portion of one of the first cladding layer or the second cladding layer. The first grating comprises alternating periodic regions of a semiconductor material and an oxidized material. Respective first gratings of the plurality of semiconductor lasers have different periods such that each laser of the plurality of semiconductor lasers is configured to produce a different wavelength than other lasers of the plurality of semiconductor lasers.

In an example embodiment, the array of semiconductors is configured as a WDM source.

According to another aspect, a method for fabricating a device is provided. For example, the device may be an optical filter, a semiconductor laser, and/or the like comprising an optical ridge waveguide. In an example embodiment, the method includes performing at least one of a selective thermal oxidation process or a selective etching process from a sidewall of a ridge waveguide or from a sidewall of a mesa structure underlying the ridge waveguide, inward toward a center of the ridge waveguide, wherein the ridge waveguide comprises a stack of epitaxial layers grown on a GaAs substrate to create buried waveguide gratings with high refractive index contrast, enabling gratings with high optical confinement factor and high coupling coefficient.

In an example embodiment, the method further includes prior to performing at least one of a selective thermal oxidation or a selective etching process, growing an initial layer stack comprising a first cladding layer, a grating layer, an active core layer, and a second cladding layer stacked in the epitaxial growth direction; etching a the second cladding layer and the active core layer in a section of the waveguide; defining a grating into the grating layer in that section; and performing a butt-joint epitaxial regrowth of a regrown core layer and a regrown second cladding layer. This is followed by defining and etching a ridge in the longitudinal direction, and an underlying mesa structure, wherein the performing the at least one of the selective thermal oxidation or a selective etching process is performed through the sidewalls of the mesa structure. The method includes performing the selective thermal oxidation, wherein the selective thermal oxidation oxidizes periodic strips in the lateral direction of the grating layer defined by the etching of the grating corrugation. The oxidation may be performed using a stack of thin aluminum containing layers or a single layer.

In an example embodiment, defining the grating into the grating layer comprises lithographically marking the grating and performing a grating corrugation etch into the grating layer, wherein the grating layer comprises a first grating material.

In an example embodiment, lithographically marking the grating comprises using E-BEAM writing or holography to define the grating.

In an example embodiment, performing the epitaxial regrowth further comprises performing epitaxial regrowth of a corrugation filling layer comprising a second grating material at least into trenches formed during the defining of the grating, and epitaxially growing above the corrugation and creating a flat surface above it.

In an example embodiment, the first grating material comprises at least one of AlAs or AlGaAs with a first Al mole fraction and the second grating material comprises at least one of GaAs, GaAlAs with a second Al mole fraction, or GaInP, wherein when the first grating material comprises AlGaAs and the second grating material comprises GaAlAs, the first Al mole fraction is greater than the second Al mole fraction.

In an example embodiment, wherein the butt-joint regrown section comprises a waveguide used to form an electro-absorption or an electro-optic external modulator.

In an example embodiment, the butt-joint regrown section comprises one or more layers configured for performing at least one of a passive waveguide function or grating waveguide function, or a modulator function.

In an example embodiment, a second grating is patterned into the grating layer following the growing of the initial layer stack, the second grating comprising alternating regions of a first semiconductor grating material having a first refractive index and a second not oxidized semiconductor grating material having a second refractive index, the first refractive index being different from the second refractive index.

In an example embodiment, the second grating is a distributed feedback and contains a quarter wavelength phase shift with respect to the first grating.

In an example embodiment, the at least one of a selective thermal oxidation or a selective etching process is performed. The method further comprises forming a silicon nitride or a silicon oxide mask with mask openings over the waveguide mesa structure and performing the selective thermal oxidation comprises performing a wet thermal oxidation process in the gratings at the mask openings through the side walls of the mesa structure to create periodic oxidized material strips forming a high contrast grating in the opening sections of the silicon nitride or silicon oxide mask.

According to another aspect, a course wavelength division multiplexing (CWDM) array or a dense wavelength division multiplexing (DWDM) array is provided. In an example embodiment, the CWDM or DWDM array includes a plurality of semiconductor lasers each configured to generate a laser beam of a respective wavelength, at least one laser of the plurality of semiconductor lasers comprises a mesa structure comprising a first cladding, a core layer, and a second cladding, a laser cavity is defined in the mesa structure at least in part by a grating comprising an oxidized material disposed between first cladding and the core layer.

According to another aspect, a datacenter is provided. In an example embodiment, the datacenter includes at least one optical interconnect, the at least one optical interconnect comprising a semiconductor laser comprising a mesa structure comprising a first cladding, a core layer, and a second cladding, a laser cavity is defined in the mesa structure at least in part by a grating with an oxidized material disposed between first cladding and the core layer.

### BRIEF DESCRIPTION OF THE SEVERAL VIEWS OF THE DRAWINGS

Reference will now be made to the accompanying drawings, which are not necessarily drawn to scale, and wherein:

FIG. 1A provides a schematic cross-sectional diagram of an example device taken in a first (lateral) plane perpendicular to a light propagation direction of the device, in accordance with certain embodiments;

FIG. 1B provides a schematic cross-sectional diagram of the example device shown in FIG. 1A taken in a second (longitudinal) plane that includes the light propagation of the device and that is perpendicular to the first plane, in accordance with certain embodiments;

FIG. 1C provides a schematic cross-sectional diagram of another example device taken in a second (longitudinal) plane that includes the light propagation of the device and that is perpendicular to the first plane, in accordance with certain embodiments;

FIG. 2 provides a schematic diagram of an example array of devices configured as a wavelength division multiplexing (WDM) source, in accordance with certain embodiments;

FIG. 3 provides a flowchart illustrating a method with various processes and/or procedures for fabricating the device illustrated in FIGS. 1A and 1B and 1C, in accordance with certain embodiments;

FIGS. 4A-4D provide cross-sectional diagrams taken in the second (longitudinal) plane illustrating various steps of fabricating a device, in accordance with certain embodiments;

FIGS. 4E-4F provide cross-sectional diagrams taken in the first (lateral) plane illustrating various steps of fabricating the device, in accordance with certain embodiments;

FIG. 5 provides a flowchart illustrating various processes and/or procedures for defining a grating, according to certain embodiments;

FIG. 6 provides a flowchart illustrating various processes and/or procedure for performing an epitaxial regrowth over a corrugated grating as part of fabricating an example device, in accordance with certain embodiments;

FIG. 7 provides a block diagram of an optical interconnect including arrays of HM devices, according to certain embodiments;

FIG. 8 provides a block diagram of an example system that may include one or more optical interconnects including devices, such as semiconductor lasers, according to certain embodiments;

FIG. 9 provides a schematic diagram of an example datacenter that may include one or more optical interconnects according to certain embodiments;

FIG. 10 provides a block diagram of two example communication devices in communication with one another according to certain embodiments;

FIGS. 11A and 11B illustrate a top view and a perspective view, respectively, of a transceiver module operatively coupled to a network adapter, in accordance with an embodiment of the disclosure.

FIG. 12 depicts some exemplary scenarios for use of an optical transceiver, in accordance with various embodiments;

FIG. 13 provides a block diagram that schematically illustrates a computing system that may include one or more optical interconnects of various embodiments;

FIG. 14 illustrates an example computing environment, in accordance with at least one embodiment;

FIG. 15 illustrates another example computer system that may include optical interconnects, according to at least one embodiment; and

FIG. 16 is a block diagram that schematically illustrates a co-packaged Networking Device, in accordance with an embodiment that is disclosed herein.

### DETAILED DESCRIPTION

The present disclosure more fully describes various embodiments with reference to the accompanying drawings. It should be understood that some, but not all embodiments are shown and described herein. Indeed, the embodiments may take many different forms, and accordingly this disclosure should not be construed as limited to the embodiments set forth herein. Rather, these embodiments are provided so that this disclosure will satisfy applicable legal requirements. Like numbers refer to like elements throughout.

Various embodiments provide devices comprising an optical ridge waveguide including a high-contrast grating. For example, in various embodiments, the optical ridge waveguide of a device includes a first cladding layer, a second cladding layer and a core layer disposed between the first cladding layer and the second cladding layer. A high-contrast grating is disposed between the core layer and a portion of one of the first cladding layer or the second cladding layer. In various embodiments, a high-contrast grating includes alternating periodic regions of a semiconductor material and an oxidized material. For example, the contrast between the index of refraction of the semiconductor material and the index of refraction of the oxidized material is approximately 1.3 or greater, in various embodiments. Since the contrast of refractive indices between semiconductor material and the oxidized material is high (e.g., in a range of 1.3-2.1, or higher) and the grating is formed in proximity to the core layer, strong gratings with high coupling coefficient are provided.

In various embodiments, the device is a semiconductor laser, such as a short cavity edge emitting semiconductor laser. For example, the cavity or resonator of the semiconductor laser may be 100 microns or shorter in length (e.g., 30-50 microns). The high-contrast grating may be used to define at least one end of the cavity or resonator of the semiconductor laser. For example, the high-contrast grating may be a Bragg reflector that defines one end of the cavity or resonator of the semiconductor laser. In some embodiments, both ends of the cavity or resonator of the semiconductor laser are defined by respective high-contrast gratings and/or Bragg reflectors.

In various embodiments, a plurality semiconductor lasers are incorporated into an array of semiconductor lasers. Each semiconductor laser of the array of semiconductors lasers may be configured to emit laser beams and/or pulses characterized by a different wavelength (e.g., such that no two semiconductor lasers of the array of semiconductor lasers emit laser beams and/or pulses that are characterized by the same wavelength). For example, the periodicity of regions of semiconductor material and oxidized material or each semiconductor laser of the array of semiconductor lasers may be tuned to cause the semiconductor lasers to emit different wavelengths. In certain embodiments, an array of semiconductor lasers is configured as a WDM source configured for performing coarse WDM and/or dense WDM sources. Semiconductor lasers and/or WDM sources of various embodiments may be incorporated into optical links.

Optical links are often used in large datacenters to communication data quickly between various portions of the datacenter. These optical links require an optical source, such as a laser, for generating the optical signals. Bandwidth requirements for these lasers continue to increase beyond currently achievable bandwidths. Therefore, technical problems exist regarding providing optical sources and/or lasers capable of next generation bandwidth and low power requirements.

Various embodiments provide technical solutions to these technical challenges. In various embodiments, semiconductor lasers are provided having small threshold currents and high differential quantum efficiency by optimizing the active length and area, as well as enhancing reflectivity through high contrast gratings (using materials with high refractive index contrast). The ability to create high contrast gratings with high reflectivity reduces the footprint of the laser and effective cavity length. In various embodiments, this is achieved by providing a short cavity semiconductor laser (e.g., having a cavity length of 100 microns or less, such as 30 microns or 40 microns) where the cavity and/or resonator of the semiconductor laser is defined, at least in part, by a high contrast grating and/or Bragg reflector. As used herein, a high contrast grating is a grating comprising alternating regions of at least two different materials and the difference or contrast in the refractive indices of two adjacent regions is greater than 1.3. For example, a cavity and/or resonator of a semiconductor laser is defined by a pair of mirrors/reflectors (e.g., with the cavity and/or resonator disposed between the pair of mirrors). At least one of the mirrors/reflectors is a high contrast grating and/or Bragg reflector.

In various embodiments, to decrease the threshold current of the semiconductor laser, the mirror reflectivity is increased by using a high contrast grating as the reflector. The refractive index contrast and the confinement factor in the grating may be increased to improve reflectivity. The grating is formed in a grating layer comprising a semiconductor material that is disposed beneath the core layer of the ridge waveguide structure of the semiconductor laser. For example, periodic corrugation trenches can be etched in an Al containing grating layer disposed between the first cladding and the core layer such that the trenches are transverse to the direction of propagation in the waveguide core layer (e.g., the trenches extend in the lateral direction). The trenches are then filled with a corrugation filling epitaxially grown material and a following regrowth process is used to form a regrown core layer and second cladding layer on the grating. A mesa may then be formed that exposes the edges of the trenches (now filled with the corrugation filling material) and an oxidization process may be performed thereon. The oxidation process starting from the sidewalls of a mesa structure, causes the regions of Al-containing material of the grating to oxidize. The resulting grating includes semiconductor-oxide interfaces which have a large refractive index difference (e.g., greater than approximately 1.3). Additionally, the grating is disposed close to the core layer which results in a high grating coupling coefficient. This provides high grating mirror reflectivity, resulting in a short cavity semiconductor laser with low threshold current and high quantum efficiency. Such a semiconductor laser has low power usage and can be externally modulated at high bandwidth. In some embodiments, the semiconductor laser may be monolithically integrated with an external modulator. Therefore, various embodiments provide technical improvements to the fields of semiconductor lasers, various devices comprising optical ridge waveguides, laser arrays, WDM sources, optical links, datacenters, and/or the like.

### Example Devices Comprising Optical Ridge Waveguides Including High-Contrast Gratings

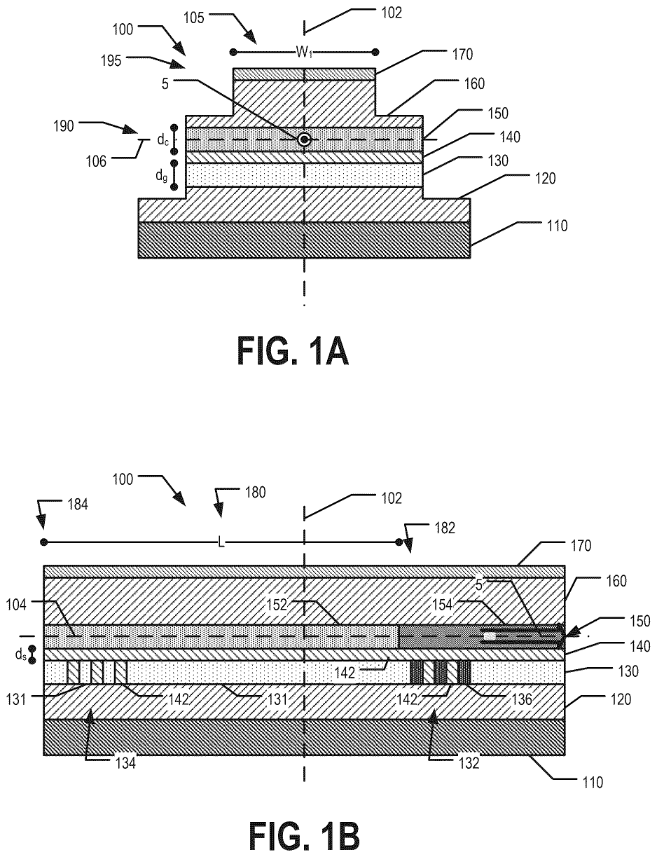

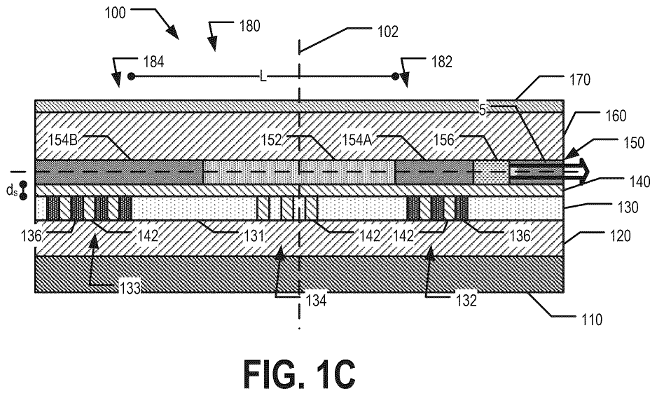

FIG. 1A provides a schematic lateral cross-sectional diagram of an example device 100 comprising an optical ridge waveguide 105 taken in a lateral plane that is perpendicular to a light propagation direction 5. The left to right direction in this plane is also referred herein as the lateral direction.

An optical ridge waveguide is a ridge structure that is formed and/or defined by a narrow mesa 170, with ridge width W₁ which defines the confinement and lateral width of the optical mode. FIG. 1B provides a schematic cross-sectional diagram of the example device 100 taken in a second plane (also referred to herein as the longitudinal plane) that is parallel to and/or including the light propagation direction 5. This direction is referred to herein as the longitudinal direction. The lateral plane and the longitudinal plane are perpendicular to one another.

In various embodiments, the device 100 comprises an optical ridge waveguide 105. The optical ridge waveguide 105 comprises a multiplicity of epitaxial layers grown sequentially along a first axis 102. The optical ridge waveguide 105 further defines the longitudinal axis 104 that is perpendicular to the first axis 102 and aligned with a light propagation direction 5 of the optical ridge waveguide 105.

In an example embodiment, the optical ridge waveguide 105 has a ridge width W₁ in the lateral direction. In various embodiments, the ridge width W₁ is in a range of 1 to 5 microns. In certain embodiments, in the longitudinal direction, the optical ridge waveguide may be hundreds of microns long.

The optical ridge waveguide 105 is formed on a substrate 110 on which multiple layers are epitaxially grown. In various embodiments, the substrate 110 is a GaAs substrate. The optical ridge waveguide 105 comprises a first cladding layer 120 disposed on the substrate 110. For example, the first cladding layer 120 may be epitaxially grown on the substrate 110. In an example, the first cladding layer 120 comprises GaAlAs and/or another cladding material.

The optical ridge waveguide 105 further comprises a grating layer 130. For example, the grating layer 130 may be epitaxially grown on the first cladding layer 120. In various embodiments, the grating layer comprises a first grating material 131. In various embodiments, the first grating material includes high aluminum (Al) content forming a epitaxial layer with high Al mole fraction. For example, first grating material comprises at least one of AlAs or AlₓGa₍₁₋ₓ₎ As with a high first Al mole fraction x, in certain embodiments.

In various embodiments, one or more grating sections (e.g., first grating section 132 and/or second grating section 134) may be formed in the grating layer 130 (FIG. 1B). For example, a first grating 132 comprises alternating periodic regions of an oxidized material 136 and a semiconductor material 142. The semiconductor material 142 also forms the separation layer 140. For example, the oxidized material 136 may be formed by selectively oxidizing the high Al content first grating material 131. The semiconductor material 142 is an un-oxidized semiconductor material epitaxially grown filling a trenches formed in the grating layer 130 and forming separation layer 140. In various embodiments, the alternating periodic regions of a first grating 132 exhibit a refractive index difference of at least 1.3 (e.g., 1.3-2.4, in some embodiments). For example, the first grating 132 may be a high contrast grating. In various embodiments, a second grating 134 comprises alternating periodic regions of the non-oxidized first grating material 131 and a second grating material (e.g., the semiconductor material 142). The refractive index contrast or difference between the first grating material 131 and the second grating material (e.g., the semiconductor material 142) is in the range of 0.2-0.5 and substantially less than the refractive index contrast or difference between the semiconductor material 142 and the oxidized material 136.

In some embodiments, the optical ridge waveguide 105 includes a filling and separation layer 140. For example, the separation layer 140 may be epitaxially grown on the grating layer 130. The separation layer 140 comprises the semiconductor material 142 that is epitaxially grown to fill the grating corrugation etched into the grating layer 130. In various embodiments, the separation layer 140 is configured to smooth and cover the grating corrugation and/or separate the grating layer 130 from the core layers 150. For example, this separation influences the confinement factor of the optical mode in the grating(s) and the grating coupling coefficient k. In various embodiments, the separation layer 140 comprises an epitaxial semiconductor material 142 such as GaAs, Ga(Al)As, GaInP, and/or a similar material.

In various embodiments, the optical ridge waveguide 105 further includes a core layers stack 150. For example, the core layers stack 150 may be epitaxially grown on the separation layer 140. The core layers stack 150 may include one or more layers such as multiple quantum wells (MQW). For example, the ridge waveguide 105 may include an active gain section 152, a passive waveguide section 154, and/or the like. For example, the various waveguide sections may be configured for performing various waveguide functions, laser functions, or a modulator functions.

In various embodiments, a first grating 132 is disposed in a passive waveguide section 154 of the ridge waveguide 105. For example, the first grating 132 may be a Bragg reflector configured to define, at least in part, a cavity or resonator of a semiconductor laser comprising the active gain section 152. For example, the device 100 may be a semiconductor laser comprising an electrically pumped active gain section 152 that is disposed within a laser cavity or resonator that is defined on one end or both ends by Bragg reflectors, such as first grating 132 and third grating 133 (FIG. 1C). In some embodiments, one end of the laser cavity or resonator is defined by a highly reflective mirror formed by cleaving, or micro-cleaving, or dry etching, and/or applying a highly reflective coating.

In various embodiments, the optical ridge waveguide 105 further includes a second cladding layer 160. For example, the second cladding layer 160 may be epitaxially grown on the core layer 150. In an example, the second cladding layer 160 comprises GaAlAs and/or another cladding material. In various embodiments, the optical ridge waveguide 105 further includes a cover layer 170. For example, the cover layer 170 may be epitaxially grown on the second cladding layer 160. In an example embodiment, the cover layer 170 comprises GaAs and/or a similar material. In some embodiments, the cover layer 170 may be a contact layer.

In various embodiments the high refractive index contrast of the first grating 132 (and third grating 133, when present) and the physical proximity of the grating layer 130 to the core layer 150 causes a strong coupling of the grating to the optical mode(s) mostly confined to the core layers stack 150. For example, in some embodiments, the grating coupling coefficient may be as high as 800-1600 cm⁻¹.

In various embodiments the separation layer 140 has a thickness in a direction aligned with the first axis 102 of a separation thickness dₛ, the grating layer 130 has a thickness in the direction aligned with the first axis 102 of a grating thickness d_{g}, and the core layer 150 has a thickness in the direction aligned with the first axis 102 of a core thickness d_{c.} In some embodiments, the grating thickness d_{g} is in a range of 50-120 nm (e.g., 50-90 nm, in some embodiments). In some embodiments, the core thickness d_{c} is in a range of 80-200 nm. In some embodiments, the separation thickness dₛ is in a range of 50-200nm (e.g., 50 -150 nm, in some embodiments). As a result of the thin separation layer 140, in addition to the high refractive index contrast of the first grating 132 (and the third grating 133, when present), a strong grating coupling coefficient is achieved.

In certain embodiments, the device 100 is an optical filter. For example, the first grating 132, formed between the passive waveguide section 154 and the first cladding 120, is configured to perform an optical filtering function. In various embodiments, the first grating 132 comprises alternating regions of a semiconductor material and an oxidized material which have a high refractive index contrast (e.g., approximately 1.3 or greater). In some embodiments, the first grating 132 is optically coupled to a passive waveguide section 154 of the waveguide 105. The first grating 132 may be a Bragg grating configured to act as an optical filter configured to only enable optical signals characterized by wavelengths within a particular wavelength range (or stopband) to be reflected.

In certain embodiments, the device 100 is a semiconductor laser (FIG. 1C). The semiconductor laser comprises at least one at least one electrically pumped active gain section 152 of the waveguide. In some embodiments, the active gain section 152 includes p-doped and n-doped cladding layers. In various embodiments, the active gain section 152 is configured to generate light when current is injected therein (e.g., via a conductive pad disposed and/or deposited on the cover layer 170 (not shown), for example). The active gain section 152 is disposed within a cavity or resonator 180 of the semiconductor laser.

In various embodiments, a first end 182 of the cavity or resonator 180 is defined by a Bragg reflector 132. For example, the first grating 132 may be a high contrast grating and/or be configured as a Bragg reflector. In an example embodiment, such as that shown in FIG. 1B, the second end 184 of the cavity or resonator 180 is defined by a cleaved, micro-cleaved, and/or etched end of the optical ridge waveguide that may have a high reflectivity coating applied thereto.

In another example embodiment shown in FIG. 1C, a second passive waveguide section 154B of the waveguide 105 extends from an end of the active gain section 152 (longitudinally) opposite the first passive waveguide section 154A (which includes the first grating 132). A third grating 133 is formed within the second passive waveguide section 154B. The third grating 133 may be configured as a Bragg reflector and/or a high contrast grating. For example, the third grating may include periodic alternating regions of a semiconductor material 142 and an oxidized material 136 having an index of refraction contrast or difference that is approximately 1.3 or higher. For example, both the first end 182 and the second end 184 of the cavity or resonator 180 may be defined by respective gratings 132, 133 (e.g., Bragg reflectors). In various embodiments, the semiconductor laser is configured to emit laser beams and/or pulses through the first grating 132. The third grating 133 may be configured to have a higher reflectivity than the first grating 132. For example, the third grating 133 may include a larger number of periodic alternating regions of the semiconductor material 142 and the oxidized material 136 compared to the first grating 132.

In various embodiments, the first end 182 and the second end 184 are configured to define a cavity or resonator 180 having a cavity length L. In various embodiments, the cavity length L is less than 100 microns.

In some embodiments, the device 100 includes a semiconductor laser that includes a distributed feedback grating. A distributed feedback grating is a periodic structure that is optically coupled to the active gain layer and is located in the active gain section 152 of the ridge waveguide 105. The distributed feedback grating may include a ¼ wavelength phase shift, which helps to ensure that the laser output is single-frequency and/or longitudinal optical mode.

For example, a second grating 134 configured as a distributed feedback grating may be disposed in an active gain section 152. In various embodiments, the second grating 134 includes periodic alternating regions of a first grating material 131 and a second grating material such as the semiconductor material 142 where neither the first grating material 131 nor the second grating material 142 is an oxidized material. The refractive index contrast or difference between the first grating material 131 and the second grating material 142 is less than the refractive index contrast or difference between the semiconductor material 142 and the oxidized material 136. For example, the refractive index contrast or difference between the first grating material 131 and the second grating material 142 may be less than 0.5, in various embodiments.

In various embodiments, the second grating 134 contains a phase shift. In certain embodiments, the second grating 134 contains a quarter wavelength phase shift. For example, the second grating 134 may be a phase-shifted Bragg grating.

In various embodiments, the first grating 132 and the second grating 134 (and the third grating 133 if present) are configured to couple to the desired output optical mode of the semiconductor laser. For example, the first grating 132 and the second grating 134 (and the third grating 133, if present) may be configured to control at what wavelength the optical modes are able to resonate within the cavity and/or resonator 180. In various embodiments, the first grating 132 and the second grating 134 (and the third grating 133 if present) are configured to not interfere with current injection of the active gain section 154.

In some embodiments, the passive waveguide section 154 of the ridge waveguide 105 may be configured to provide a laser beam and/or pulse train emitted by the semiconductor laser (e.g., via the first grating 132) to an external modulator. In some embodiments, ridge waveguide 105 may include (e.g., possibly embedded in a passive waveguide following waveguide section 154A, as shown in FIG. 1C) a modulator section 156. For example, the modulator section 156 may be in electrical communication with one or more electrical pads and the modulator section 156 may be configured to have an optical property that is dynamically adjustable (e.g., via application of an electrical signal to the one or more electrical pads) to modulate the laser beam and/or pulse train emitted by the semiconductor laser. For example, the semiconductor may be externally modulated via a monolithically integrated modulator, in certain embodiments.

In various embodiments, the device 100 comprising an optical ridge waveguide 105 having a first grating comprising periodic alternating regions of semiconductor material and oxidized material (yielding an index of refraction contrast and/or difference of approximately 1.3 or greater) where the first grating is disposed between a cladding layer 120 and/or 160 and a core layers stack 150 of the optical ridge waveguide 105. The ridge waveguide 105 may comprise a variety of passive and/or active optical sections and/or devices.

### Example Array of Semiconductor Lasers

In various embodiments, an array of devices 100 comprising an optical ridge waveguide 105 having a first grating comprising periodic alternating regions of semiconductor material and oxidized material (yielding an index of refraction contrast and/or difference of approximately 1.3 or greater) where the first grating is disposed between a cladding layer 120 and/or 160 and a core layer 150 of the optical ridge waveguide 105 are provided.

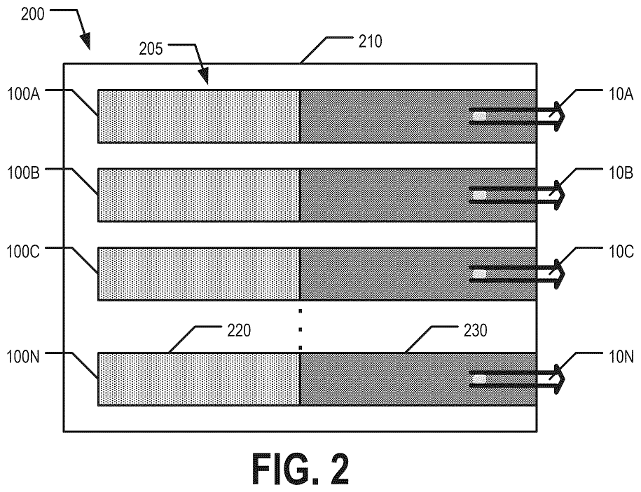

FIG. 2 illustrates an array 200 of devices 100. The array 200 comprises a plurality of devices 100A, 100B, 100C, . . . , 100N that are configured as a WDM source 205. In various embodiments, a WDM source is configured for performing coarse WDM (CWDM) or dense WDM (DWDM). For example, a WDM source is configured to generate a plurality of spectral wavelengths that may independently have a respective data stream encoded thereon. The plurality of spectral wavelengths may be combined to form an optical signal carrying a plurality of data streams carried inside a single optical fiber.

In the illustrated embodiment, each device 100A-N of the array 200 includes a respective active gain section 220 and a respective passive waveguide section 230. For example, each of the devices 100A-N is a respective semiconductor laser having a respective cavity and/or resonator that is defined on at least one end by a Bragg reflector, such as first grating 132 and/or third grating 133.

In various embodiments, each of the devices 100A-N emits a laser beam and/or pulses 10A, 10B, 10C, . . . , 10N characterized by a respective wavelength. In various embodiments, the Bragg reflectors of the devices 100A-N (e.g., the respective first gratings 132 and possibly third gratings 133) and/or distributed feedback gratings (e.g., the second grating 134) are configured such that each of the devices 100A-N emits a laser beam and/or pulse 10A-N that is unique within the array 200. For example, a first device 100A emits a first laser beam and/or pulse train 10A characterized by a first wavelength λ_{A}, a second device 100B emits a second laser beam and/or pulse train 10B characterized by a second wavelength λ_{B}, a third device 100C emits a third laser beam and/or pulse train 10C characterized by a third wavelength λ_{C}, and a Nth device 100N emits an Nth laser beam and/or pulse train 10N characterized by an Nth wavelength λ_{N}. The Bragg reflectors of the devices 100A-N (e.g., the respective first gratings 132 and possibly third gratings 133) are configured such that the first wavelength λ_{A} is different from each of the second, third, . . . , and Nth wavelengths λ_{B}-λ_{N}. For example, λ_{A}≠λ_{B}≠λ_{C}≠. . .≠λ_{N}. For example, the respective first gratings 132 of the plurality of devices 100A-N (e.g., semiconductor lasers) have different periods such that each laser of the plurality of semiconductor lasers 100A-N is configured to produce a different wavelength than other lasers of the plurality of semiconductor lasers.

In an example embodiment, the Bragg reflectors of the devices 100A-N (e.g., the respective first gratings 132 and possibly third gratings 133) and/or distributed feedback gratings (e.g., the second grating 134) are configured such that the m^{th} wavelength of the plurality of wavelengths λ_{A}-λ_{N} is given as λ_{A}+mΔλ, where Δλ is a wavelength step between adjacent spectral lines of the WDM source 205. In various embodiments, the WDM source 205 is configured to perform coarse or dense WDM.

### Example Method of Fabricating a Device Comprising an Optical Ridge Waveguide Including a High-contrast Grating

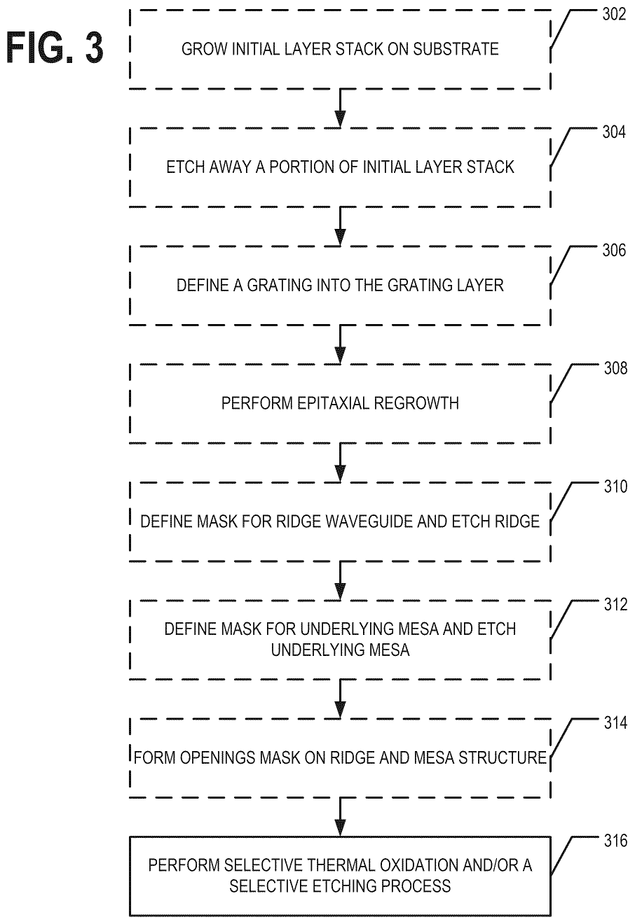

FIG. 3 provides a flowchart illustrating various processes and/or procedures performed to fabricate a device 100 comprising an optical ridge waveguide 105 having a first grating comprising periodic alternating regions of semiconductor material and oxidized material (yielding a high index of refraction contrast and/or difference (e.g., approximately 1.3 or greater)) where the first grating is disposed between a cladding layer 120 and/or 160 and a core layer 150 of the optical ridge waveguide 105.

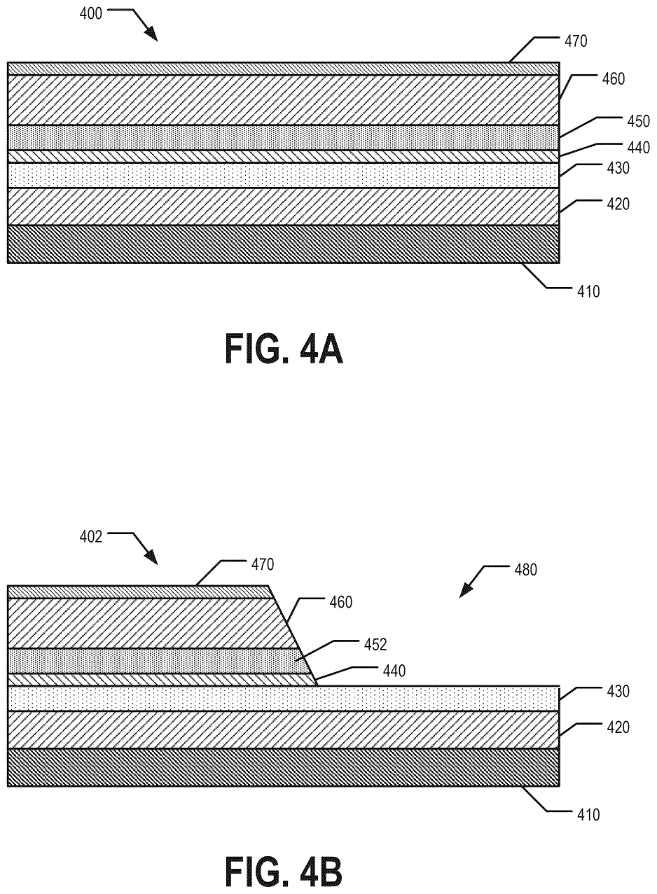

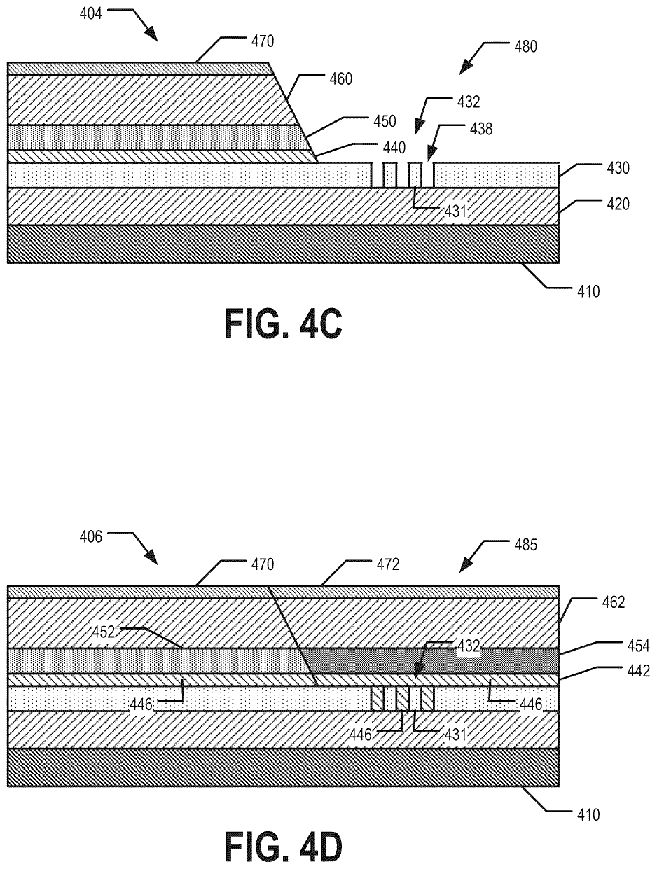

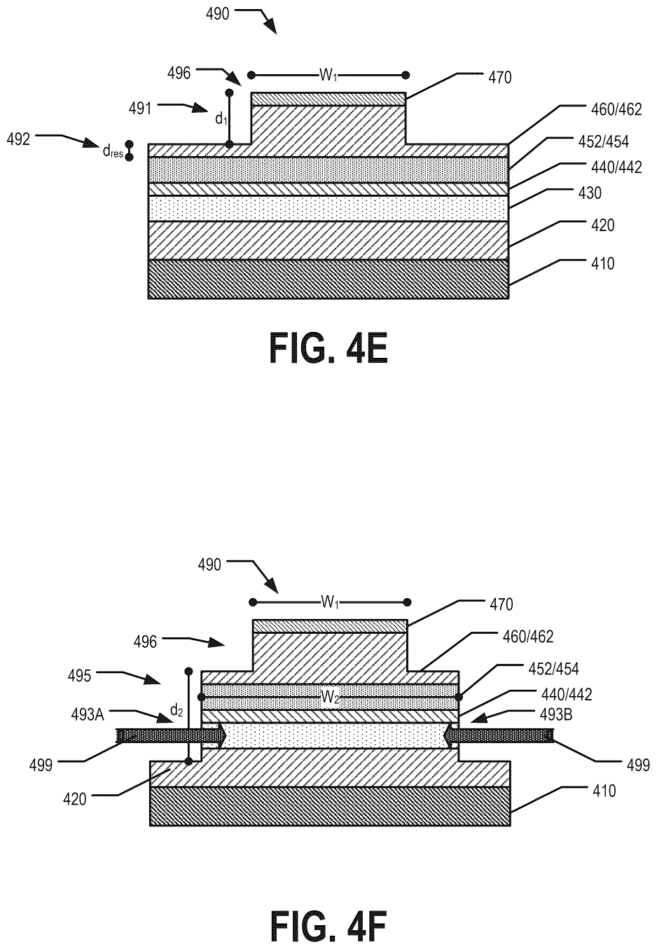

Starting at block 302, an initial layer stack is epitaxially grown on a substrate. FIG. 4A illustrates a cross-sectional view of an example initial layer stack 400 epitaxially grown on the substrate 410, where the layers of the initial layer stack 400 are stacked and/or arranged in a direction along a first axis 102. In various embodiments, the initial layer stack 400 includes a first cladding layer 420 epitaxially grown on the substrate 410. In an example, the first cladding layer 420 comprises GaAlAs and/or another cladding material.

The initial layer stack 400 further includes a grating layer 430 epitaxially grown on the first cladding layer 420. In various embodiments, the grating layer 430 comprises a first grating material that may include Al. For example, first grating material comprises at least one of AlAs or AlGaAs with a high Al mole fraction, in certain embodiments. The initial layer stack 400 further includes a separation layer 440 epitaxially grown on the grating layer 430. In various embodiments, the separation layer 440 comprises a semiconductor material such as GaAs, Ga(Al)As, GaInP, and/or a similar material.

In various embodiments, the initial layer stack 400 further includes a core layer stack 450 epitaxially grown on the separation layer 440. In an example embodiment where the device includes an active gain section, the core layer 450 may include an active gain section material. For example, the core layer 450 may be an undoped layer stack with multi-quantum well (MQW) layers, and/or the like configured to generating light and positioned between p-doped and n-doped cladding layers,

In various embodiments, initial layer stack 400 further includes a second cladding layer 460 deposited or epitaxially grown on the core layer 450. In an example, the second cladding layer 460 comprises GaAlAs and/or another cladding material. In some embodiments, the initial layer stack further includes a cover layer 470 deposited or epitaxially grown on the second cladding layer 460. In an example embodiment, the cover layer 470 comprises GaAs and/or a similar material. In some embodiments it may be highly P-doped to provide a good ohmic contact.

In some embodiments, growing the initial layer stack 400 comprises forming the second grating 134 within the grating layer. For example, the grating layer 430 may be epitaxially grown on the first cladding layer 420. The second grating may then be defined in the grating layer 430, for example, by lithographically marking the grating and then performing a grating corrugation etch based at least in part on the marking of the grating. For example, lithographically marking the grating may result in a mask that may be used to perform the grating corrugation etch. Performing the grating corrugation etch results in a plurality of trenches formed in the grating layer 430. A second grating material (e.g., semiconductor 446) may be epitaxially grown on and/or in the grating layer 430 to fill the trenches. In an example embodiment, the separation layer 440 may be formed of the same semiconductor material 446 as the second grating material.

Continuing with FIG. 3, at block 304, a portion of the initial layer stack 400 is etched away. For example, a butt joint mask (e.g., an SiO₂ mask) may be patterned onto the initial layer stack 400 and used to etch away a portion of the initial layer stack. In some embodiments, the etching is performed using a dry etch technique, such as inductively coupled plasma (ICP), reactive ion etching (RIE), and/or the like. In some embodiments, the etching is performed using a wet etch technique, such as a chemically selective wet etch, and/or the like. In some embodiments, a combination of dry and wet etch techniques are used to remove a portion of the initial layer stack 400.

FIG. 4B illustrates the result of etching away a portion of the initial layer stack 400 using a butt joint mask. For example, a portion of the cover layer 470, second cladding layer 460, core layer 450, and a portion of the separation layer 440 may be etched away to provide an access opening 480 via which a portion of the grating layer 430 is accessible. In the illustrated embodiment, the portion of the core layer 452 that is not etched away includes an active gain section 402 of the ridge waveguide.

Continuing with FIG. 3, at block 306, a grating is defined into the grating layer 430. For example, the first grating may be defined into the grating layer 430 via the access opening 480. As shown in FIG. 4C, defining the grating 432 into the grating layer 430 comprises etching a plurality of trenches 438 into the first grating material 431 of the grating layer 430. For example, the plurality of trenches 438 may be etched so as to provide periodic alternating regions of the first grating material 431 and ambient atmosphere (e.g., air and/or the atmosphere under which the processing of the in-progress device 404 is performed).

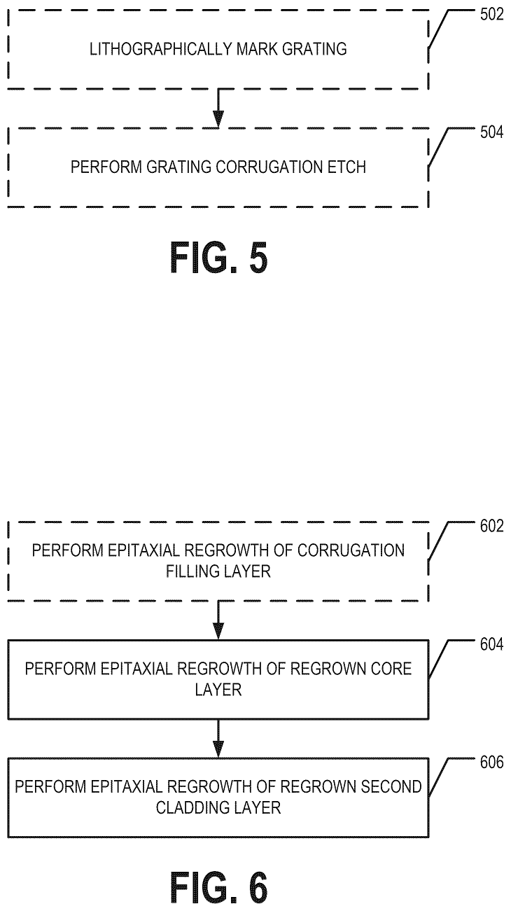

FIG. 5 provides a flowchart illustrating various processes and/or procedures that may be used, in various embodiments, to define a grating into a grating layer 430. Starting at block 502, the grating is lithographically marked. In various embodiments, lithographically marking the grating includes preparing a mask on a surface of the grating layer 430. Various lithographic mask preparation and/or patterning techniques may be used to lithographically mark the grating. For example, in some embodiments, electron beam (E-BEAM) writing or holography is used to lithographically mark the grating on the grating layer 430.

At block 504, a grating corrugation etch is performed based at least in part on the lithographic marking of the grating. For example, as shown in FIG. 4C, the grating corrugation etch is performed to etch the trenches 438 into the grating layer 430 leaving periodic strips of the Al containing first grating material 431 of the grating layer between the trenches, in accordance with the lithographic mask prepared on the surface of the grating layer 430. The grating corrugation etch may be performed using a dry etch or wet etch, in various embodiments.

Returning to FIG. 3, at block 308, epitaxial regrowth is performed to grow the refill and separation layer 442 with semiconductor material 446 (which may be identical to layer 440) to fill the trench openings of trenches 438 and create the smooth top of the refill and separation layer 442. For example, as shown in FIG. 4D, a regrown layer stack 485 is provided by regrowing the filling and separation layer 442 which may be identical to separation layer 440, followed by second core layers 454 and second cladding layer 462 and cover layer 472.

FIG. 6 provides a flowchart illustrating various processes and/or procedures that may be performed in order to perform an epitaxial regrowth to provide the regrown layer stack 485. Starting at block 602, an epitaxial regrowth is performed to form a corrugation filling and separation layer 442. For example, the semiconductor material 442 may be epitaxially regrown so as to fill the trenches 438 of the grating 432 and form a separation layer above it.

In an example embodiment, the filling and separation layer 442 may be formed of the semiconductor material 446 GaAs, GaAlAs, or GaInP. For example, performing the epitaxial regrowth to form the corrugation filling layer may also include forming the regrown separation layer 442.

At block 604, an epitaxial regrowth of the regrown core layer 454 is performed. For example, the regrown core layer 454 may be epitaxially regrown on the regrown separation layer 442. In some embodiments, the regrown core layer 454 includes and/or forms a passive waveguide section of the core layer. The regrown core layer 454 may also include one or more sections configured to provide a modulator function of the resulting device. In various embodiments, the regrown core layer 454 is aligned along the second longitudinal axis 104 with the active gain section of the core layer.

At block 606, an epitaxial regrowth of the regrown second cladding layer 462 is performed. For example, a regrown second cladding layer 462 may be grown on the regrown core layer 454. In some embodiments, a regrown cover layer 472 may be regrown on the regrown second cladding layer 462.

Returning to FIG. 3, at block 310, a ridge mask for the ridge waveguide is defined and/or formed on the regrown layer stack 406 and a first ridge structure of an optical ridge waveguide is etched from the regrown layer stack 406. For example, as shown in FIG. 4E, the regrown layer stack 406 may be patterned to include a ridge waveguide 496 with a ridge width W₁ and a ridge depth d₁.. The ridge etch depth 491 is terminated just before the core layers stack (including the active section 452 and the passive waveguide section 454) with a residual distance dᵣₑₛ 492. The residual thickness dres is configured to control the optical mode shape and confinement factor in the core and grating layers.

Returning to FIG. 3, at block 312, a mesa mask is defined and/or formed and etching an underlying mesa structure 495 is etched such that the ridge waveguide 496 is disposed on the mesa structure 495, as shown in FIG. 4F. The mesa structure is defined to have a mesa width W₂ that is larger than the ridge width W₁. The mesa width W₂ may be larger than the ridge width W₁ by 2-5 um. The underlying mesa etch depth d₂ is large enough to penetrate through the grating layer 430 and stop in the first cladding layer 420.

At block 314, an oxidation mask is patterned on the ridge waveguide structure 490 comprising the mesa structure 495 and the ridge waveguide 496. For example, a silicon nitride or a silicon oxide mask may be formed on the ridge waveguide structure 490 such that mask openings define locations of selective thermal oxidation or selective etching of the mesa structure to be performed. In some embodiments, the mask openings are aligned with the grating sections. For example, the mask openings may be aligned with portions of the grating layer 430 that will yield the first grating 132 and the third grating 133 of FIG. 1C. In various embodiments, the oxidation mask controls which portions of the grating layer 430 are exposed to an oxidation process and protects other portions of the grating layer 430 from being oxidized.

At block 316, a selective thermal oxidation process and/or a selective etching process may be performed on the mesa structure via the oxidation mask. The thermal oxidation process takes place through the side walls of the mesa structure 493A and 493B shown in FIG. 4F. The oxidation process is affecting the first grating material 431 (shown in FIG. 4C) due to its high Al contents. The oxidation process penetrates into the semiconductor first grating material 431 from both sides of the underlying mesa structure, as shown by the arrows 499 in FIG. 4F. The oxidation process may be continued until the oxidation penetration from the sidewalls 493A, 493B meets at the lateral center of the waveguide 105. It should be noted that the oxidation process does not affect the filling material 446 (FIG. 4D.). Thus, the oxidized first grating material 431 and the filling material 446 form a periodic high contrast grating 132 between oxidized and unoxidized semiconductor material.

In various embodiments, the selective thermal oxidation process and/or selective etching process is performed to cause the first grating 132 (and/or a third grating 133) to be a high contrast grating. For example, a selective thermal oxidation may be performed to cause the first grating 132 (and/or the third grating 133) to oxidize periodic regions of a first grating 132 (and/or third grating 133) such that the grating is a high contrast grating comprising periodic alternating regions of a semiconductor material and an oxidized material. In another example, a selective etching process may be performed to cause the first grating 132 (and/or the third grating 133) to form periodic regions of a first grating 132 (and/or third grating 133) such that the grating is a high contrast grating comprising periodic alternating regions of a semiconductor material and air. In various embodiments, the selective thermal oxidation process and/or the selective etching process is performed through the mask openings in the mask patterned onto the mesa structure.

In various embodiments, the selective thermal oxidation is performed from a sidewall of the optical ridge waveguide inward toward the center of the optical ridge waveguide (e.g., in a lateral direction parallel to the third axis 106 toward the center of the waveguide 102). In certain embodiments, the selective thermal oxidation process is a wet thermal oxidation process. For example, in various embodiments, the optical ridge waveguide is placed into a furnace and exposed to a high temperature (e.g., 400-480 °C) and water vapor. The water vapor interacts with the first grating material 431 exposed via the mask openings. As a result, the first grating material 431 (which includes high Al content) is oxidized inward from the sidewall and/or surface of the mesa structure 495 toward the center of the ridge mesa (axis 102). In some embodiments, the selective thermal oxidation is performed for a selected amount of time configured to cause oxidation to occur for a desired depth into the mesa structure 105 (e.g., in the lateral direction). In some embodiments, the selective thermal oxidation is performed for a sufficient time for the oxidation to be complete across the width of the mesa structure 495. Depending on the mole fraction x of the aluminum in the first grating material 431, the process temperature, the layer thickness (e.g., grating period), and/or the like, the sufficient time for the oxidation to be complete across the mesa width W₂ of the mesa structure 495 may be in a range of 1 or 2 minutes up to 1 to 2 hours.

In various embodiments, the selective etching process is performed from a sidewall of the optical ridge waveguide in toward the center of the optical ridge waveguide (see arrows 499 in FIG. 4F). In certain embodiments, a grating was defined in the grating layer at block 306 and a corrugation filling layer was deposited and/or regrown to fill the trenches formed during the defining of the grating. In such an embodiment, the selective etching process is performed to remove the high Al content regions of first grating material disposed between the regions of the corrugation filling layer. For example, a chemically selective etch may be used to form periodic alternating regions of a semiconductor material 446 and air/ambient environment. In such an embodiment, an opening mask may be used to perform the selective etching process.

The regions of air may extend from the sidewall 493A, 493B into the ridge structure 490 of the optical ridge waveguide. In some embodiments, the regions of air extend all the way through the mesa structure 495. In some embodiments, the regions of air extend only part way under the ridge waveguide 490. In some embodiments, the regions of air extend into the mesa structure 495 but do not extend under the ridge waveguide 490.

After performance of the selective thermal oxidation and/or selective etching process, one or more cleaning processes may be performed on the optical ridge waveguide to, for example, remove any masks patterned onto the mesa structure. In various embodiments, contact pads for injecting current into an active gain section of the waveguide and/or for operating a modulator section of the optical ridge waveguide.

It should be noted that the several consecutive epitaxial layers can be grown in one (combined) epitaxial growth step, with different combinations, and that the block diagrams of FIGS. 3, 5-6 are just an illustration of one example of a possible process flow chart, and other combinations of layers and flow charts are possible.

### Example Optical Interconnect Including an Array of Semiconductor Lasers

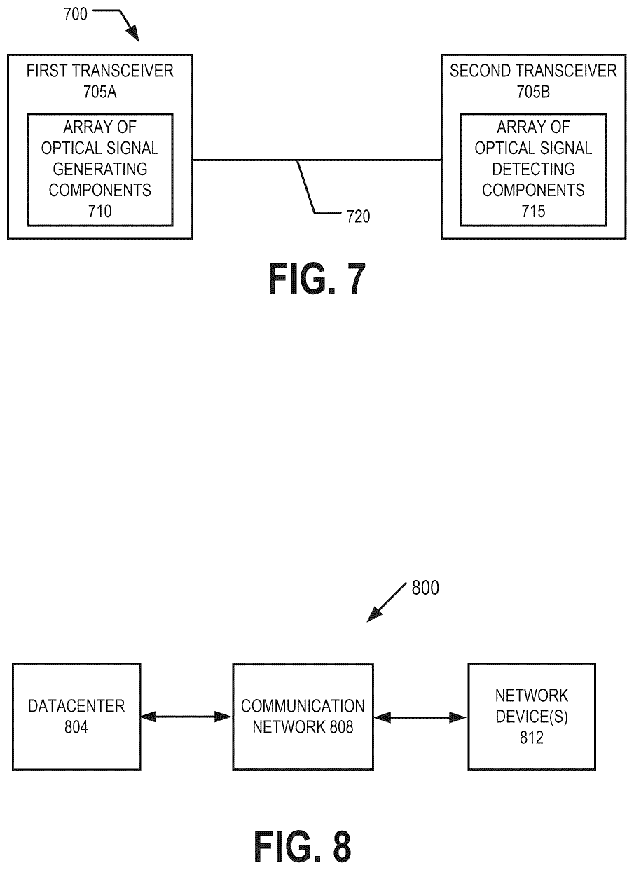

FIG. 7 illustrates an example optical interconnect 700 including one or more devices 100 of various embodiments. For example, an optical interconnect 700 may include optical filters, semiconductor lasers, one or more WDM sources, and/or the like that are devices 100 in accordance with various embodiments. As should be understood, devices 100 of various embodiments may be incorporated into a variety of components, assemblies, and/or systems. Optical interconnects including one or more devices 100 of various embodiments are illustrated herein to provide an example of one such component, assembly, and/or system in which devices 100 of various embodiments may be incorporated.

The optical interconnect 700 comprises a first transceiver 705A and a second transceiver 705B. The first transceiver 705A is in optical communication with the second transceiver 705B via one or more optical fibers 720. The first transceiver 705A comprises one or more devices 100. For example, the one or more devices 100 of the array of optical signal generating components 710 may be optical filters, an array 200 of semiconductor lasers, a WDM source 205, and/or the like. In various embodiments, the array of optical signal generating components 710 are configured to generate a plurality of spectral lines (e.g., with one spectral line generated by each semiconductor laser of the array 200). In an example embodiment, each spectral line may be modulated such that a respective digital data stream is encoded therein.

The second transceiver 705B comprises an array of optical signal detecting components 715. In various embodiments, the array of optical signal detecting components 715 is an array of photodiodes, photodetectors, and/or other optical signal detecting devices. In various embodiments, the optical signal detecting components of the array of optical signal detecting components 715 are configured to receive respective optical signals via optical filters. In various embodiments, the optical filters are devices 100, in accordance with various embodiments.

For example, the first transceiver 705A comprises a WDM source 205 configured to generate a plurality of spectral lines that are modulated to provide a WDM optical signal having, possibly, multiple channels of data encoded therein. The WDM optical signal is then provided to the second transceiver 705B via the optical fiber 720, for example. One or more optical signal detecting components that may include respective photodiodes and/or other photodetectors may receive and/or detect respective portions of the optical signal (e.g., corresponding to respective spectral lines) such that information is communicated from the first transceiver 705A to the second transceiver 705B via the optical signal(s).

### Example Datacenter

In various embodiments, a system includes one or more devices 100, in accordance with various embodiments. For example, a WDM source 205 may be used as a coarse or dense WDM optical source of a transceiver of an optical link. For example, as shown in FIG. 7, WDM sources comprising devices 100 of various embodiments may be incorporated into an optical interconnect. Such an optical interconnect may be part of a datacenter.

For example, an optical interconnect comprising one or more devices 100 (e.g., optical filters, semiconductor lasers, and/or the like) of various embodiments may be used to place various components of a datacenter in communication with one another. In various embodiments, the system may include a pluggable optical interconnect, a chip-to-chip optical interconnect, an optical network comprising a plurality of optical interconnect, dense Wavelength Division Multiplexing (WDM) optical links, WDM or DWDM source and/or the like that includes one or more WDM sources 205 of various embodiments. For example, a WDM source 205 may be configured to generate optical signals that are transmitted along one or more optical communication paths between two components of a datacenter, in accordance with an example embodiment.

Datacenters may include multiple network switches in a particular topology, such as a fat tree topology, a slim fly topology, a dragonfly topology, and/or the like. The specifications and makeup of the network switches in the topology affects the overall network performance (e.g., bandwidth capability) of the datacenter.

Datacenters are the storage and data processing hubs of the internet. The massive deployment of cloud applications is causing datacenters to expand exponentially in size, stimulating the development of faster switches than can cope with the increasing data traffic inside the datacenter. Current state-of-the-art switches are capable of handling 12.8 Tb/s of traffic by employing electrical switches in the form of application specific integrated circuits (ASICs) equipped with 256 data lanes, each operating at 50 Gbps. Such switching ASICs typically consume as much as 400 W, and the power consumption of the optical transceiver interfaces attached to each ASIC is comparable. To keep pace with traffic demand, switch capacity doubles approximately every two years. To date, this rapid scaling has been made possible by exploiting advances in manufacturing (e.g., CMOS techniques), collectively described by Moore's law (i.e., the observation that the number of transistors in a dense integrated circuit doubles about every two years). However, in recent years there are strong indications of Moore's law slowing down, which raises concerns about the capability to sustain the target scaling rate of switch capacity. As a result, alternative technologies are being investigated.

FIG. 8 illustrates a system 800 according to at least one example embodiment. The system 800 includes a datacenter 804, a communication network 808, and one or more network devices 812. In at least one example embodiment, the datacenter 804 corresponds to a collection of network devices, such as network switches (e.g., Ethernet switches) connected with a collection of servers or compute nodes. The datacenter 804 may adhere to a networking topology (e.g., a hierarchal networking topology), such as a fat tree topology, a Slim Fly topology, a Dragonfly topology, and/or the like. The datacenter 804 routes traffic amongst the network switches and servers therein, and at least one layer of the topology in the datacenter 804 is coupled to the communication network 808 to allow networking traffic to flow between the datacenter 804 and the network device(s) 812.

Examples of the communication network 808 that may be used to connect the datacenter 804 and the network device(s) 812 include an Internet Protocol (IP) network, an Ethernet network, an InfiniBand (TB) network, a Fibre Channel network, the Internet, a cellular communication network, a wireless communication network, combinations thereof (e.g., Fibre Channel over Ethernet), variants thereof, and/or the like.

The one or more network devices 812 may include switch, router, or Network Interface Controller (NIC), interconnect using ports, one or more of Personal Computer (PC), a laptop, a tablet, a smartphone, a server, a collection of servers, and/or any suitable computing device for sending and receiving signals over the communication network 808. In at least one example embodiment, the one or more network devices 812 correspond to another datacenter, similar to or the same as datacenter 804.

As noted above, the datacenter 804 and/or the network device(s) 812 may include storage devices and/or processing circuitry for carrying out computing tasks, for example, tasks associated with controlling the flow of data internally and/or over the communication network 808. Such processing circuitry may comprise software, hardware, or a combination thereof. For example, the processing circuitry may include a memory including executable instructions and a processor (e.g., a microprocessor) that executes the instructions on the memory. The memory may correspond to any suitable type of memory device or collection of memory devices configured to store instructions. Non-limiting examples of suitable memory devices that may be used include Flash memory, Random Access Memory (RAM), Read Only Memory (ROM), variants thereof, combinations thereof, or the like. In some embodiments, the memory and processor may be integrated into a common device (e.g., a microprocessor may include integrated memory).

Additionally or alternatively, the processing circuitry may comprise hardware, such as an application specific integrated circuit (ASIC). For example, the processor may be or include one or more of an Integrated Circuit (IC) chip, a microprocessor, a Central Processing Unit (CPU), a Graphics Processing Unit (GPU), a Data Processing Unit (DPU), a Field Programmable Gate Array (FPGA), a network interface controller (NIC), an ASIC, combinations thereof, and the like. The processing circuitry may comprise an ASIC and/or may be capable of performing as a central processing unit (CPU), a graphics processing unit (GPU), a network interface controller (NIC), a data processing unit (DPU), or any other computing device in which with data is received and/or transmitted.

Some or all of the processing circuitry may be provided on a Printed Circuit Board (PCB) or collection of PCBs. It should be appreciated that any appropriate type of electrical component or collection of electrical components may be suitable for inclusion in the processing circuitry.

In addition, although not explicitly shown, it should be appreciated that the datacenter 804 and network device(s) 812 may include one or more communication interfaces for facilitating wired and/or wireless communication between one another and other unillustrated elements of the system 800.

In related art systems, a fat tree topology may use the same electrical switching devices on all layers (edge, aggregation, core). For example, each switching device may be 1 U switch, where 1 U refers to the industry standard size for rack-mounted switch and/or server. The interconnection between switches of different layers may be accomplished with optical links or optical interconnects using active optical cables and optical transceivers implemented in a pluggable form factor (also referred to as “pluggables”).

Optical Datacenter Networks rely on allocation and deallocation of light paths from the data sources to the destinations end-ports to guarantee no light collisions and data loss occur in the fabric. Traditionally the allocation algorithms are run from a central entity which considers the entire demand for source and destination flows and try to find the most dense mapping of these demands to network resources over a single or multiple time periods.

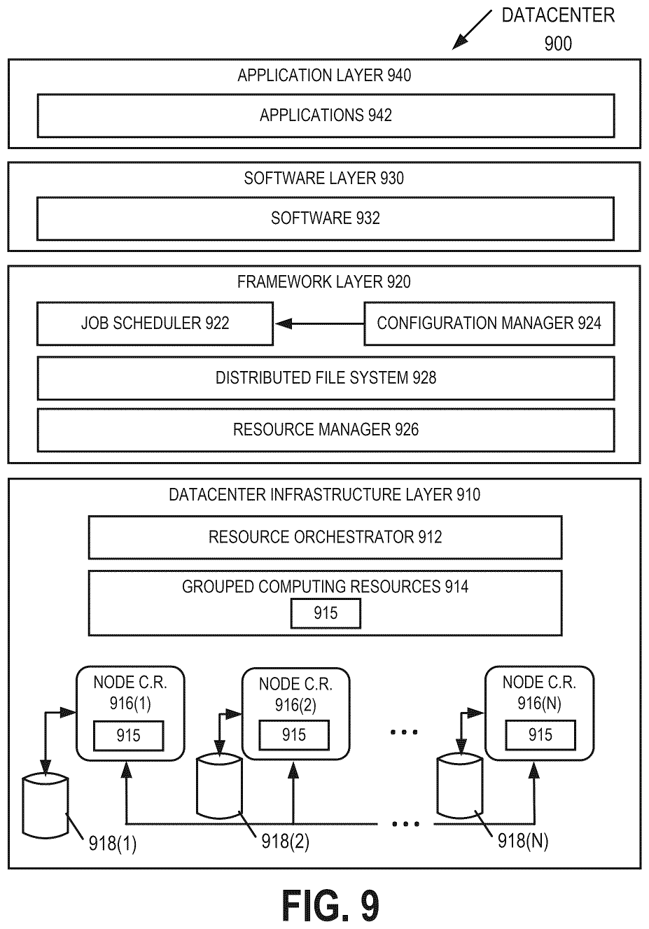

FIG. 9 illustrates an example datacenter 900, in which at least one embodiment may be used. In at least one embodiment, datacenter 900 includes a datacenter infrastructure layer 910, a framework layer 920, a software layer 930, and an application layer 940.

In at least one embodiment, as shown in FIG. 9, datacenter infrastructure layer 910 may include a resource orchestrator 912, grouped computing resources 914, and node computing resources (“node C.R.s”) 916(1)-916(N), where “N” represents a positive integer (which may be a different integer “N” than used in other figures). In at least one embodiment, node C.R. s 916(1)-916(N) may include, but are not limited to, any number of central processing units (“CPUs”) or other processors (including accelerators, field programmable gate arrays (FPGAs), graphics processors, etc.), memory storage devices 918(1)-918(N) (e.g., dynamic read-only memory, solid state storage or disk drives), network input/output (“NW I/O”) devices, network switches, virtual machines (“VMs”), power modules, and cooling modules, etc. In at least one embodiment, one or more node C.R.s from among node C.R.s 916(1)-916(N) may be a server having one or more of above-mentioned computing resources.

In at least one embodiment, grouped computing resources 914 may include separate groupings of node C.R.s housed within one or more racks (not shown), or many racks housed in datacenters at various geographical locations (also not shown). In at least one embodiment, separate groupings of node C.R.s within grouped computing resources 914 may include grouped compute, network, memory, or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 912 may configure or otherwise control one or more node C.R.s 916(1)-916(N) and/or grouped computing resources 914. In at least one embodiment, resource orchestrator 912 may include a software design infrastructure (“SDI”) management entity for datacenter 900. In at least one embodiment, resource orchestrator 912 may include hardware, software or some combination thereof.

In at least one embodiment, as shown in FIG. 9, framework layer 920 includes a job scheduler 922, a configuration manager 924, a resource manager 926 and a distributed file system 928. In at least one embodiment, framework layer 920 may include a framework to support software 932 of software layer 930 and/or one or more application(s) 942 of application layer 940. In at least one embodiment, software 932 or application(s) 942 may respectively include web-based service software or applications, such as those provided by Amazon Web Services, Google Cloud and Microsoft Azure. In at least one embodiment, framework layer 920 may be, but is not limited to, a type of free and open-source software web application framework such as Apache Spark™ (hereinafter “Spark”) that may utilize distributed file system 928 for large-scale data processing (e.g., “big data”). In at least one embodiment, job scheduler 922 may include a Spark driver to facilitate scheduling of workloads supported by various layers of datacenter 900. In at least one embodiment, configuration manager 924 may be capable of configuring different layers such as software layer 930 and framework layer 920 including Spark and distributed file system 928 for supporting large-scale data processing. In at least one embodiment, resource manager 926 may be capable of managing clustered or grouped computing resources mapped to or allocated for support of distributed file system 928 and job scheduler 922. In at least one embodiment, clustered or grouped computing resources may include grouped computing resources 914 at datacenter infrastructure layer 910. In at least one embodiment, resource manager 926 may coordinate with resource orchestrator 912 to manage these mapped or allocated computing resources.

In at least one embodiment, software 932 included in software layer 930 may include software used by at least portions of node C.R. s 916(1)-916(N), grouped computing resources 914, and/or distributed file system 928 of framework layer 920. In at least one embodiment, one or more types of software may include, but are not limited to, Internet web page search software, e-mail virus scan software, database software, and streaming video content software.

In at least one embodiment, application(s) 942 included in application layer 940 may include one or more types of applications used by at least portions of node C.R. s 916(1)-916(N), grouped computing resources 914, and/or distributed file system 928 of framework layer 920. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 924, resource manager 926, and resource orchestrator 912 may implement any number and type of self-modifying actions based on any amount and type of data acquired in any technically feasible fashion. In at least one embodiment, self-modifying actions may relieve a datacenter operator of datacenter 900 from making possibly bad configuration decisions and possibly avoiding underutilized and/or poor performing portions of a datacenter.

In at least one embodiment, datacenter 900 may include tools, services, software, or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to datacenter 900. In at least one embodiment, trained machine learning models corresponding to one or more neural networks may be used to infer or predict information using resources described above with respect to datacenter 900 by using weight parameters calculated through one or more training techniques described herein.

In at least one embodiment, datacenter may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 915 are used to perform inferencing and/or training operations associated with one or more embodiments. In at least one embodiment, inference, and/or training logic 915 may be used in system FIG. 9 for inferencing or predicting operations based, at least in part, on weight parameters calculated using neural network training operations, neural network functions and/or architectures, or neural network use cases described herein.

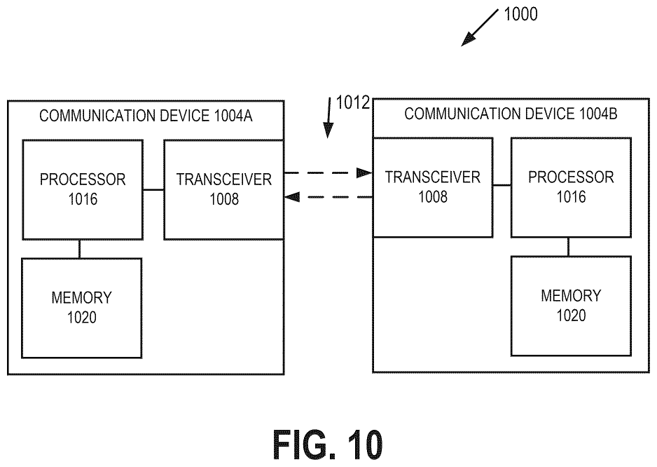

FIG. 10 illustrates a system 1000 including a first communication device 1004A and a second communication device 1004B. Illustratively, but without limitation, the communication devices 1004 (e.g., 1004A, 1004B) may correspond to network devices (e.g., network devices 812). As such, the communication devices 1004 may correspond to any type of device that becomes part of or is connected with a communication network (e.g., communication network 808). Examples of suitable devices that may act or operate like a communication device 1004 as described herein include, without limitation, one or more of a Personal Computer (PC), a laptop, a tablet, a smartphone, a server, a collection of servers, a networking card, an edge router, a switch, Network Interface Controller, a Top of Rack (ToR) switch, a server blade, or the like. The communication device 1004 may include a transceiver 1008, a processor 1016, and memory 1020. The transceiver 1008 may include hardware that enables communications over the communication channel 1012 whereas the processor 1016 and memory 1020 may include components that enable the communication device 1004 to provide a desired functionality or perform certain functions.

The communication channel 1012 may traverse a datacenter or any type of communication network (whether trusted or untrusted). Examples of a communication network that may be used to connect communication devices 1004 and support the communication channel 1012 include, without limitation, an Internet Protocol (IP) network, an Ethernet network, an InfiniBand (IB) network, a Fibre Channel network, the Internet, a cellular communication network, a wireless communication network, combinations thereof (e.g., Fibre Channel over Ethernet), variants thereof, and/or the like. In one specific, but non-limiting example, the communication network enables data transmission between the communication devices 1004 using optical signals. In this case, the communication devices 1004 and the communication network may include waveguides (e.g., optical fibers) that carry the optical signals. For example, the communication devices and/or the communication network may include one or more WDM sources 205 and/or other devices 100, according to various embodiments.

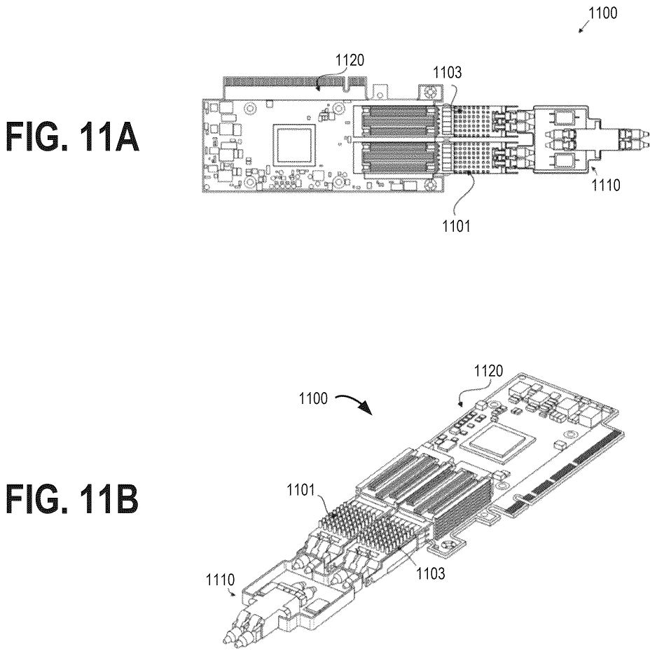

FIGS. 11A and 11B illustrate a top view and a perspective view, respectively, of a transceiver module operatively coupled to a network adapter, in the present example a Network Interface Controller (NIC) 1100, in accordance with an embodiment of the disclosure. As shown in FIGS. 11A and 11B, the transceiver module may include a first optical module 1101, a second optical module 1103, an adapter 1110, and a dual-port NIC 1120 of a server. Both the first optical module 1101 and the second optical module 1103 may be dual-fiber transceivers that are configured for duplex communication that allows the source (e.g., server) to communicate with the target (e.g., leaf switch) in both directions. The adapter 1110 may be a ganged physical component configured to link the first optical module 1101 and the second optical module 1103 for the purpose of transmitting and receiving data to and from the leaf switch.

In some embodiments, the adapter 1110 may be configured to operate in two configurations, such as a first configuration and a second configuration. In one aspect, the first configuration may be a default configuration of operation, where the first optical module 1101 may be operationally active. The second configuration may be a contingent configuration that is implemented when the first optical module 1101 operationally fails. When such a failure is detected, the second optical module 1103, which is otherwise operationally inactive or idle, may be engaged become operationally active and handle all network traffic that was initially handled by the first optical module 1101.

In some embodiments, the transceiver module 1100 may be configured to operate in a leaf-spine architecture. A leaf-spine architecture is a data center network topology that may include two switching layers—a spine layer and a leaf layer. The leaf layer may include access switches (leaf switches) that aggregate traffic from servers and connect directly into the spine or network core. Spine switches interconnect all leaf switches in a full-mesh topology between access switches in the leaf layer and the servers from which the access switches aggregate traffic. As such, in one embodiment, to ensure reliable operation of downlinks, the transceiver module 1100 may be configured to operate between the server and the leaf layer. In particular, as shown in FIGS. 11A and 11B, the adapter 1110 may be operatively coupled to the first optical module 1101 and the second optical module 1103, while the first optical module 1101 and the second optical module 1103 may be operatively coupled to a dual-port NIC 1120 of a server.

In embodiments, NIC 1100 may comprise one or more processing circuits, as detailed above; the processing circuits may comprise FW, that is loaded according to the techniques described above.

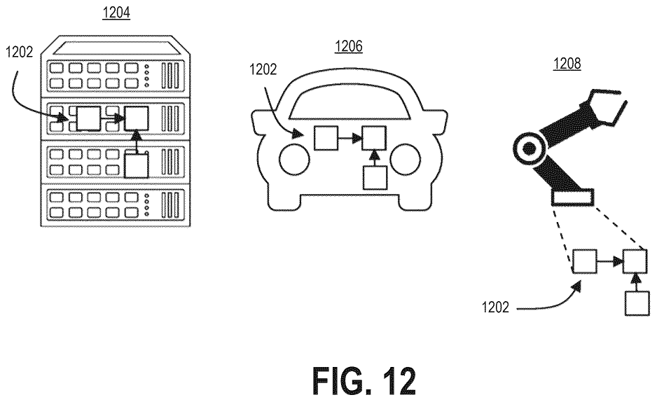

FIG. 12 depicts some exemplary scenarios for use of an optical transceiver 1202 in accordance with some embodiments. An optical transceiver 1202 may be utilized in a computing system 1204 (e.g., in a server farm, or within a server computer system), a vehicle 1206 (e.g., a car, truck, train, or airplane), and a robot 1208 (or among robots in a factory), to name just a few examples. The optical transceiver 1202 may be particularly useful for high-speed communication in environments subject to high levels of electromagnetic interference (EMI).

### Example System Use Case

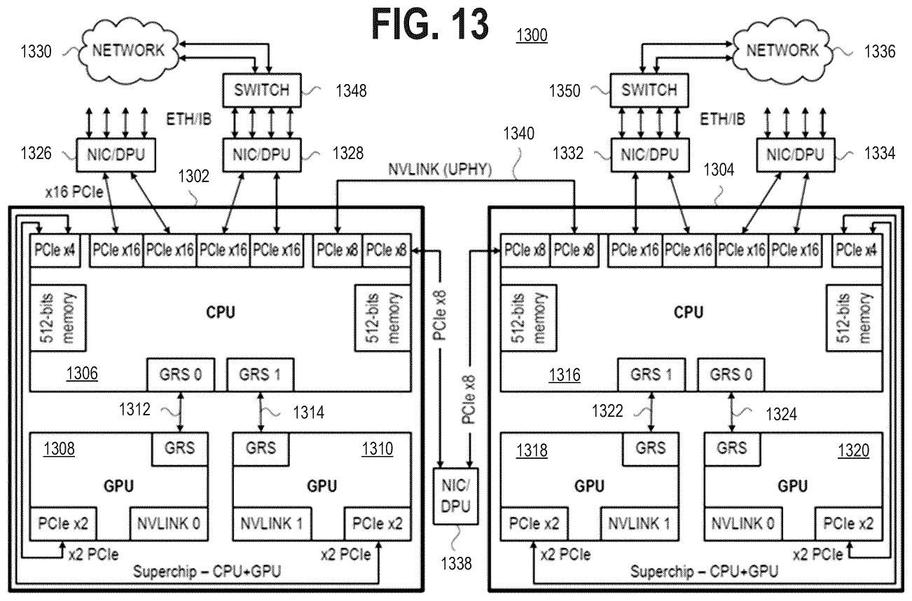

FIG. 13 is a block diagram that schematically illustrates a computing system 1300, e.g., a data center or a High-Performance Computing (HPC) cluster, in accordance with an embodiment that is described herein. System 1300 comprises a plurality of subsystems, e.g., multiple processing devices coupled to each other, multiple network devices, and multiple networks, according to at least one embodiment. Computing system 1300 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 1300 and to one or more external networks 1330, 1336. In the present example, system 1300 comprises a packet switch 1348 that connects NIC/DPU 1328 to network 1330, and a packet switch 1350 that connects NIC/DPU 1332 to network 1336.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1300 can include one or more CPUs and one or more GPUs.

FIG. 13 also demonstrates an example architecture of a multi-GPU architecture. As illustrated in the figure, computing system 1300 includes a processing device 1302 with a multi-GPU architecture. In particular, processing device 1302 may be a system-on-chip and includes multiple subsystems such as a CPU 1306, a GPU 1308, and a GPU 1310. CPU 1306 can be coupled to GPU 1308 via a die-to-die (D2D) or chip-to-chip (C2C) interconnect 1312, such as a Ground-Referenced Signaling interconnect (GRS interconnect). CPU 1306 can be coupled to GPU 1310 via a D2D or C2C interconnect 1314. CPU 1306 can also couple to GPU 1308 and GPU 1310 via PCIe interconnects.

CPU 1306 can be coupled to one or more NICs or DPUs, which are coupled to one or more networks. For example, as illustrated in FIG. 3, CPU 1306 is coupled to a first NIC/DPU 1326, which is coupled to a network 1330. CPU 1306 is also coupled to a second NIC/DPU 1328, which is coupled to network 1330 via switch 1348. NIC/DPU 1326 and NIC/DPU 1328 can be coupled to network 1330 over Ethernet (ETH), NVLINK or InfiniBand (IB) connections, for example.

Computing system 1300 also includes a processing device 1304 with a multi-GPU architecture. In particular, processing device 1304 includes multiple subsystems including a CPU 1316, a GPU 1318, and a GPU 1320. CPU 1316 can be coupled to GPU 1318 via an D2D or C2C interconnect 1322. CPU 1316 can be coupled to GPU 1320 via a D2D or C2C interconnect 1324. CPU 1316 can also couple to GPU 1318 and GPU 1320 via PCIe interconnects. CPU 1316 can be coupled to one or more NICs or DPUs, which are coupled to one or more networks. For example, as illustrated in FIG. 3, CPU 1316 is coupled to a first NIC/DPU 1332, which is coupled to a network 1336. CPU 1316 is also coupled to a second NIC/DPU 1334, which is coupled to network 1336 via switch 1350. NIC/DPU 1332 and NIC/DPU 1334 can be coupled to network 1336 over Ethernet (ETH), NVLINK or InfiniBand (IB) connections.

In at least one embodiment, processing device 1302 and processing device 1304 can communication with each other via a NIC/DPU 1338, such as over PCIe interconnects. Processing device 1302 and processing device 1304 can also communicate with each other over a high-bandwidth communication interconnects 1340, such as an NVLink interconnect or other high-speed interconnects. The packet switches in FIG. 3 may comprise, for example, Nvidia Quantum-2 switches. The NICs/DPUs in the figure may comprise, for example, Nvidia Bluefield DPUs.

In various embodiments, one or more of the interconnects 1312, 1314, 1322, 1324 may be optical interconnects disclosed herein. Additionally, in various embodiments, switches 1348, 1350 may be in communication with NIC/DPU 1328, 1332, respectively, via one or more optical interconnects disclosed herein. In some embodiments, NIC/DPU 1326, 1334 may be in communication with one or more additional elements via optical interconnects disclosed herein. For example, various elements of the computing system 1300 may be in communication with one another via one or more optical interconnects disclosed herein.

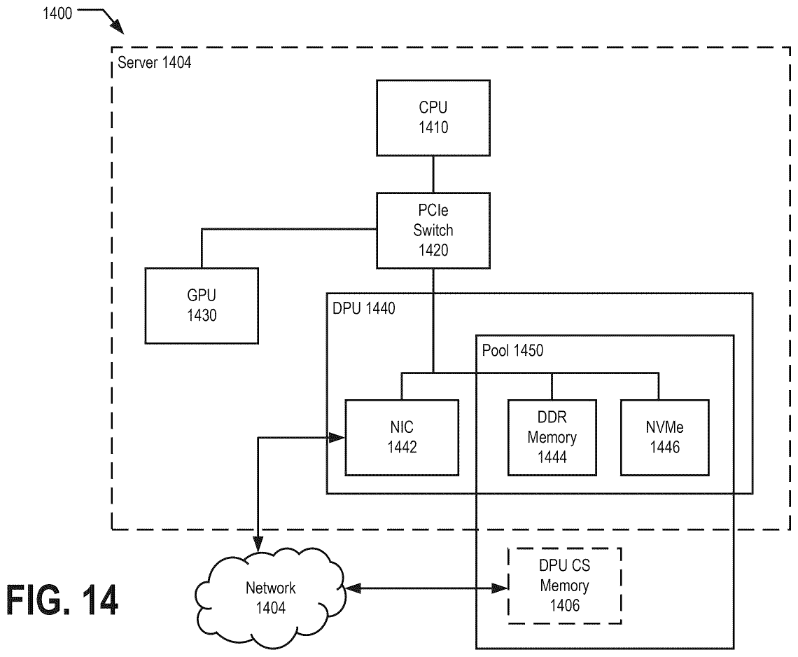

FIG. 14 illustrates an example computing environment 1400 in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures. The example computing environment 1400 may include a server 1402 which may be used to perform high performance computing (HPC) workloads, such as AI training or machine learning model training. In an embodiment, the server 1402 may be an application instance or a compute node. The server 1402 may include a CPU 1410 associated with a switch 1420, such as a peripheral component interconnect express (PCIe) switch, which may control at least some data transmission over communication paths interconnecting various components. In an embodiment, the CPU 1410 may include a root complex processor.

The PCIe switch 1420 may also be associated with a GPU 1430 and a DPU 1440, and may transmit data between at least some of the CPU 1410, the GPU 1430, the DPU 1440, and other components (e.g., via one or more optical interconnects disclosed herein). In an embodiment, the PCIe switch 1420 may be associated with more than one GPU or more than one DPU. In another embodiment, the PCIe switch 1420 may be located within the DPU 1440. The PCIe switch 1420 may manage the transfer of at least some data between the CPU 1410, the GPU 1430, and the DPU 1440. In another embodiment, the number of GPUs associated with the PCIe switch 1420 may be equal to the number of DPUs associated with the PCIe switch 1420. In at least one embodiment, the server 1402 may include, without limitation, any number of the CPUs 1410, the PCIe switches 1420, the GPUs 1430, and/or the DPUs 1440, in any combination. For example, in at least one embodiment, server 1402 could include eight, sixteen, thirty-two, and/or more GPUs 1430. In at least one embodiment, communication paths interconnecting various components, including but not limited to the CPU 1410, the PCIe switch 1420, the GPU 1430, and the DPU 1440, in FIG. 14 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 1440 may include a network interface controller (NIC) 1442, a DDR memory 1444, and a non-volatile memory express (NVMe) device 1446. The NIC 1442 may be able to interface with a network 1404, which may also interface with additional NVMe devices available to the DPU 1440, such as over fabric. In an embodiment, the DPU 1440 may not include the NVMe device 1446. In another embodiment, the NVMe device 1446 may be located on the server 1402 and not on the DPU 1440. In yet another embodiment, the computing environment 1400 may include more than one of the NVMe device 1446, such as a first NVMe device in the DPU 1440 and a second first NVMe device on the server 1402 an associated directly with the PCIe switch 1420. In an embodiment, the DPU 1440 may not include the DDR memory 1444 and may include a computational storage services (CSS) in place of, or in addition to, the DDR memory 1444. For example, computing environment 1400 may include DPU computational storage (CS) memory 1406 available to the DPU 1440 as part of the CSS. The network 1404 may be able to interface with the DPU CS memory 1406 through the NIC 1442, according to any suitable interface protocol, such as remote direct memory access (RDMA) over Ethernet, InfiniBand, Fiber Channel, etc.

The total memory of the computing environment 1400 available for data storage may be expanded through the use of the DPU 1440 on nodes of the system. The DPU 1440 may have access to a pool 1450 of memory already available to the server 1402, such as double data rate (DDR) memory, on-board NVMe devices, NVMe devices over fabric, and CS. The pool 1450 of memory may include at least one of the DDR memory 1444, NVMe 1446, and the DPU CS memory 1406. The DPU 1440 may also be able to access the available memory of other DPUs as part of the pool 1450, and other DPUs may be able to access the available memory of DPU 1440, such as the pool 1450. This available memory can be accessed and utilized for data storage, without the addition of compute resources, such as compute nodes, which would be required using other solutions. The available pool 1450 accessible to the DPU 1440 may be provisioned for the server 1402 to expand the total memory available for data storage, such as to reduce the data storage load on the CPU 1410 or the GPU 1430, which can instead increase the utilization of their memory for processing. For example, during training of an AI, the model states, residual states, activation functions, and checkpoints can be stored, or offloaded, on the pool 1450 accessible to the DPU 1440.

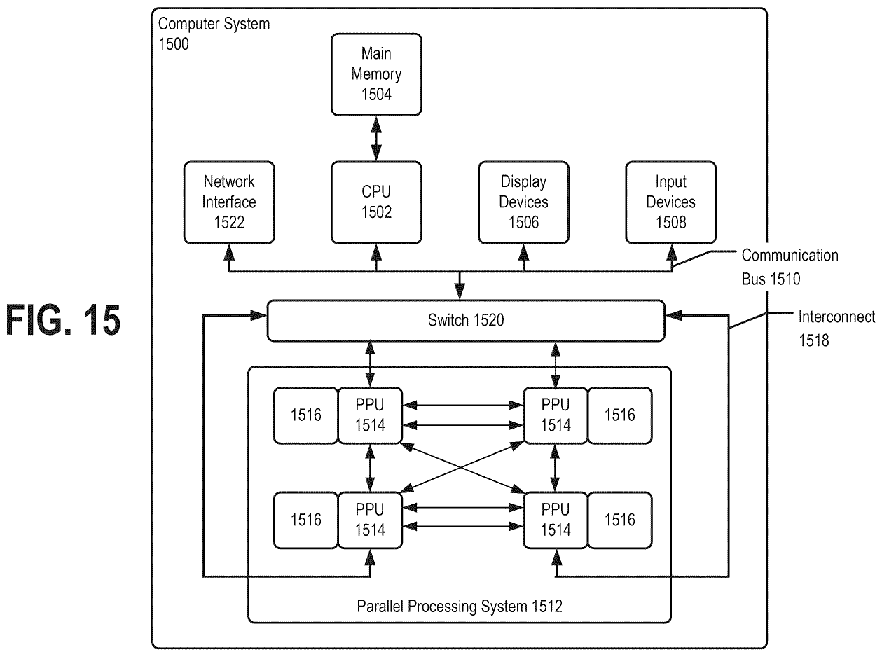

FIG. 15 illustrates a computer system 1500, according to at least one embodiment. In at least one embodiment, computer system 1500 comprises at least one optical interconnect of an example embodiment.

In at least one embodiment, computer system 1500 comprises, without limitation, at least one central processing unit (“CPU”) 1502 that is connected to a communication bus 1510 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 1500 includes, without limitation, a main memory 1504 and control logic (e.g., implemented as hardware, software, or a combination thereof) and data are stored in main memory 1504 which may take form of random access memory (“RAM”). In at least one embodiment, a network interface subsystem (“network interface”) 1522 provides an interface to other computing devices and networks for receiving data from and transmitting data to other systems from computer system 1500.

In at least one embodiment, computer system 1500, in at least one embodiment, includes, without limitation, input devices 1508, parallel processing system 1512, and display devices 1506 which can be implemented using a conventional cathode ray tube (“CRT”), liquid crystal display (“LCD”), light emitting diode (“LED”), plasma display, or other suitable display technologies. In at least one embodiment, user input is received from input devices 1508 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 1504 and/or secondary storage. Computer programs, if executed by one or more processors, enable system 1500 to perform various functions in accordance with at least one embodiment. memory 1504, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 1502; parallel processing system 1512; an integrated circuit capable of at least a portion of capabilities of both CPU 1502; parallel processing system 1512; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 1500 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 1512 includes, without limitation, a plurality of parallel processing units (“PPUs”) 1514 and associated memories 1516. In at least one embodiment, PPUs 1514 are connected to a host processor or other peripheral devices via an interconnect 1518 and a switch 1520 or multiplexer. In at least one embodiment, parallel processing system 1512 distributes computational tasks across PPUs 1514 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 1514, although such shared memory may incur performance penalties relative to use of local memory and registers resident to a PPU 1514. In at least one embodiment, operation of PPUs 1514 is synchronized through use of a command such as_syncthreads(), wherein all threads in a block (e.g., executed across multiple PPUs 1514) to reach a certain point of execution of code before proceeding.

The PPUs 1514 may be in communication with one another and/or switch 1520 via one or more optical interconnects in accordance with example embodiments disclosed herein.

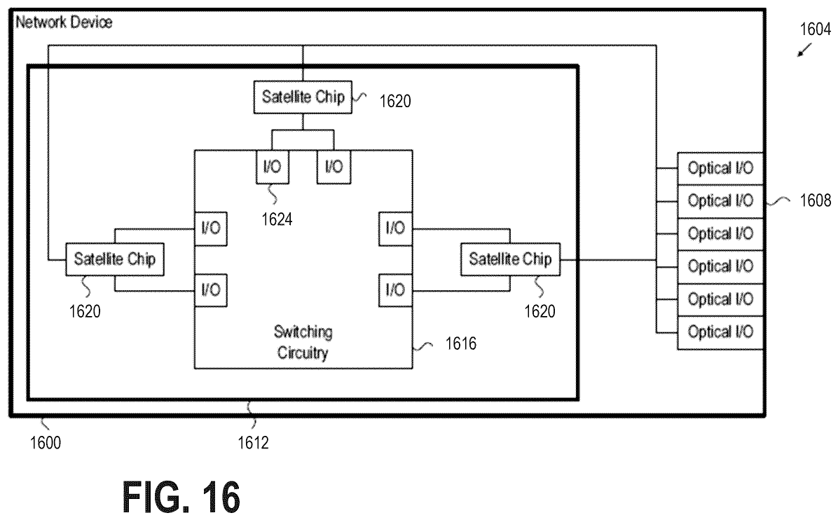

Co-packaging may refer to the close integration of different electrical and/or optoelectronic chips in the same package. FIG. 16 is a block diagram that schematically illustrates a co-packaged Networking Device 1600, in accordance with an embodiment that is disclosed herein. The different chips that constitute a co-packaged Networking Device are assembled on a single substrate in what is typically called the MCM assembly 1612. The MCM assembly 1612 can include a switching circuitry 1616 surrounded by peripheral or satellite chips 1620. In some embodiments, the switching circuitry 1616 and surrounding satellite chips 1620 are all mounted on a common substrate, although such a configuration is not required. The MCM assembly 1612 may be provided in a larger housing of the networking device 1612, positioned behind the front panel 1604. The switching circuitry 1616 may include one or more core digital Application Specific Integrated Circuits (ASICs), CPUs, GPUs, microprocessors, FPGAs, combinations thereof, and the like. The switching circuitry 1616 may include a number of input ports and/or output ports 1628. The Input/Output (I/O) ports 1624 may include electrical ports and/or optical ports. Additionally, the switching circuitry 1616 may include a combination of electrical blocks and optical blocks. The electrical blocks of the switching circuitry 1616 may include a number of electrical switches that are configured to route signals in an electrical domain. The optical blocks of the switching circuitry 1616 may include a number of optical components that are configured to generate, detect, and route signals in an optical domain. The MCM assembly 1612, in some embodiments, may concern or include multiple satellite chips 1620 that are assembled on the same substrate as the switching circuitry 1616. In some embodiments, a configuration of the optical block(s) and a configuration of the electrical block(s) depends (e.g., is based on) on the number of optical ports in the I/O ports 1624.

As discussed above, optical I/Os 1608, which may also be referred to as optical connectors, are placed at the front panel 1604. As mentioned above, connectivity between the MCM assembly 1612 and optical I/Os 1608 may be transferred to the front panel 1604 through optical fibers. This connection may be made directly with an optical I/O 1624 of the switching circuitry or may be made with one or more of the satellite chips 1620. The connection is often made with one or more of the satellite chips 1620 because the satellite chips 1620 may include the electro-optic converters and, possibly, the serializer/deserializer (SERDES) to natively support the connection. The satellite chips 1620 may include one or more of aDSP processor, driver, trans-impedance amplifier, laser, modulator, photodiode, serializer-deserializer, or the like.

Some embodiments of the present disclosure are directed to a multi-chip module (MCM) with a centrally positioned main die and a plurality of peripherally positioned MCM sockets configured to mechanically receive and electrically connect mezzanine packages, which may include co-packaged optics (CPO) packages and co-packaged copper (CPC) packages. Each mezzanine package may include a package substrate including a connector portion that is configured to engage the MCM socket and a main portion extending beyond the periphery of the MCM substrate. The main portion of the mezzanine package may be configured to receive optical devices and/or integrated circuits, such as via mezzanine sockets, to allow connections to be made between the optical devices and/or integrated circuits/RF copper cable connectors and the main die of the MCM. Due to the extension of the mezzanine package beyond the periphery of the MCM substrate, the physical size of the MCM substrate may remain small to reduce cost and avoid the previously discussed production challenges, while allowing connections to a number of optical devices and integrated circuits via the mezzanine packages, which occupy the relatively inexpensive space around the periphery of the MCM substrate. As used herein, the terms “co-packaged optic” (or “CPO”) and “co-packaged copper” (or “CPC”) may refer to an advanced heterogeneous integration of either optics and silicon or copper and silicon, in which either integration may be implemented on a single packaged substrate. The CPO may utilize pluggable optical modules that include an optical engine (OE) to convert optical signals to electrical signals and electrical signals to optical signals. The CPO may further be comprised of an optical component on a photonics die and an electrical component on an electrical die.

As used herein, a ball grid array (BGA) may be a type of surface-mount packaging used for integrated circuits. BGA packages use an array of metallic conductor balls arranged in a grid to permanently mount devices such as microprocessors on a PCB. The metallic conductor balls may then undergo the reflow process described above, wherein the metallic conductor balls may be preheated, then melted to bond the IC to a substrate to form an IC package.

As used herein, the term “flip chip (FC)” may refer to a method for interconnecting dies, such as semiconductor devices, IC chips, integrated passive devices, and microelectromechanical systems (MEMS), to external circuitry with solder bumps that have been deposited onto chip pads. The solder bumps may be deposited onto chip pads on the top side of the wafer during final wafer processing. The chip may be mounted to external circuitry (such as a circuit board or another chip or wafer) by “flipping” the chip, such that the chip's top side faces down and is positioned to allow the pads of the chip to align with matching pads on the external circuit. Solder is reflowed to complete the interconnect.

### Conclusion

Many modifications and other embodiments will come to mind to one skilled in the art to which this disclosure pertains having the benefit of the teachings presented in the foregoing descriptions and the associated drawings. Therefore, it is to be understood that the disclosure is not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A device comprising an epitaxially grown semiconductor waveguide comprising an optical ridge waveguide, wherein the optical ridge waveguide comprises at least:
a first cladding layer;
a second cladding layer;
a stack of core layers disposed between the first cladding layer and the second cladding layer; and
a first grating disposed between the core layer and one of the first cladding layer or the second cladding layer, wherein the first grating comprises alternating periodic regions of a semiconductor material and an oxidized material.

2. The device of claim 1, wherein the device is a semiconductor laser and further comprises an active gain waveguide section comprising p-doped and n-doped cladding layers and the stack of core layers of the semiconductor waveguide are longitudinally aligned with the active gain waveguide section.

3. The device of claim 2, wherein a second grating is located in the active gain section, the second grating comprising alternating periodic regions of a first semiconductor grating material and a second semiconductor grating material, a refractive index contrast between the first semiconductor grating material and the second semiconductor grating material being smaller than a refractive index contrast between the semiconductor material and the oxidized material.

4. The device of claim 3, wherein the first grating and the second grating are coupled to an optical mode of semiconductor laser, and the first grating and the second grating do not interfere with the current injection in the active gain section.

5. The device of claim 3, wherein the second grating is a distributed feedback grating and contains a quarter wavelength phase shift.

6. The device of claim 2, further comprising a third grating disposed between the core layer and one of the first cladding layer or the second cladding layer, wherein the third grating comprises alternating periodic regions of the semiconductor material and an oxidized material, wherein the third grating is disposed on a longitudinally opposite end of the active gain section with respect to the first grating.

7. The device of claim 6, wherein the first grating consists of a first number of periodic alternating regions and the third grating consists of a third number of periodic alternating regions, and the third number is more than the first number.

8. The device of claim 1, wherein the first grating is an optical waveguide filter in a passive waveguide section.

9. An array of semiconductor lasers comprising:
a plurality of semiconductor lasers, each semiconductor laser of the plurality of semiconductor lasers comprising at least:
a first cladding layer;
a second cladding layer;
a core layer stack disposed between the first cladding layer and the second cladding layer; and
a first grating disposed between the core layer stack and one of the first cladding layer or the second cladding layer, wherein the first grating comprises alternating periodic regions of a semiconductor material and an oxidized material,
wherein respective first gratings of the plurality of semiconductor lasers have different periods such that each laser of the plurality of semiconductor lasers is configured to produce a different wavelength than other lasers of the plurality of semiconductor lasers.

10. A method for fabricating a device, the method comprising:
performing at least one of a selective thermal oxidation or a selective etching process from a sidewall of a ridge waveguide or from a sidewall of a mesa structure underlying the ridge waveguide, inward toward a center of the ridge waveguide, to form a first high refractive index contrast grating formed between periodic regions of semiconductor material and oxidized material, in a section of the ridge waveguide comprising epitaxial layers grown on a GaAs substrate.

11. The method of claim 10, wherein
performing the selective thermal oxidation through the sidewalls of a ridge waveguide mesa structure oxidizes periodic strips in the grating layer defined by the etching of a grating corrugation.

12. The method of claim 11, further comprising forming a silicon nitride or a silicon oxide mask with mask openings over the ridge waveguide mesa structure and performing the thermal oxidation process selectively only where there are mask openings at the sidewalls of the waveguide mesa structure.

13. The method of claim 10, further comprising defining a grating into the grating layer to form a grating corrugation, wherein defining the grating into the grating layer comprises lithographically marking the grating and performing a grating corrugation etch into the grating layer, wherein the grating layer comprises a first grating material with high Al mole fraction.

14. The method of claim 13, wherein lithographically marking the grating comprises using E-BEAM writing or holography to define the grating.

15. The method of claim 13, further comprising epitaxially regrowing a corrugation filling layer comprising regrowth of a second grating material at least into trenches formed during the etching of the grating corrugation.

16. The method of claim 15, wherein the first grating material comprises at least one of AlAs or AlGaAs with a first Al mole fraction and the second grating material comprises at least one of GaAs, GaAlAs with a second Al mole fraction, or GaInP, wherein when the first grating material comprises AlGaAs and the second grating material comprises GaAlAs, the first Al mole fraction is greater than the second Al mole fraction.

17. The method of claim 10, further comprising:
prior to performing the at least one of a selective thermal oxidation or a selective etching process from a sidewall of a ridge waveguide or from a sidewall of a mesa structure underlying the ridge waveguide, etching away a portion of an initial layer stack;
defining a grating into a grating layer of the initial layer stack, wherein the grating layer was exposed by the etching away of the portion of the initial layer stack; and
performing an epitaxial regrowth to form one or more regrown waveguide sections, wherein at least one regrown waveguide section of the one or more regrown waveguide sections comprises one or more p-n doped cladding layers and one or more sections of the regrown waveguide are used to form an electro-absorption or an electro-optic external modulator.

18. The method of claim 17, wherein respective regrown waveguide sections of the one or more regrown waveguide sections are configured for performing at least one of a passive waveguide function, a laser function, or a modulator function.

19. The method of claim 17, wherein a second grating is patterned into the grating layer during a growing of the initial layer stack, the second grating comprising alternating regions of a first non-oxidized semiconductor grating material having a first refractive index and a second non-oxidized semiconductor grating material having a second refractive index, the first refractive index being different from the second refractive index.

20. The method of claim 19, wherein the second grating is a distributed feedback Bragg grating and contains a quarter wavelength phase shift.

21. A course wavelength division multiplexing (CWDM) array or a dense wavelength division multiplexing (DWDM) array, comprising:
a plurality of semiconductor lasers each configured to generate a laser beam of a respective wavelength, at least one laser of the plurality of semiconductor lasers comprises a mesa structure comprising a first cladding, a core layer, and a second cladding, a laser cavity is defined in the mesa structure at least in part by a high contrast grating using periodically oxidized material disposed between first cladding and the core layer.

22. A datacenter comprising:
at least one optical interconnect, the at least one optical interconnect comprising a semiconductor laser comprising a mesa structure comprising a first cladding, a core layer, and a second cladding, a laser cavity is defined in the mesa structure at least in part by a grating disposed between first cladding and the core layer, comprising an oxidized grating material.
